(19) United States
(12) Patent Application Publication
(10) Pub. No.: US 2026/0026241 A1
(43) Pub. Date: Jan. 22, 2026

(54) DISPLAY DEVICE, METHOD FOR MANUFACTURING THE SAME, AND ELECTRONIC DEVICE INCLUDING THE SAME

(71) Applicant: Samsung Display Co., LTD., Yongin-si (KR)

(72) Inventor: YOUNGJAE JEON, Yongin-si (KR)

(21) Appl. No.: 19/067,555

(22) Filed: Feb. 28, 2025

(30) Foreign Application Priority Data
Jul. 16, 2024 (KR) 10-2024-0093612

(51) Int. Cl. H10K 59/80; H10K 59/12; H10K 59/124; H10K 59/131; H10K 59/38

(52) U.S. Cl. CPC H10K 59/873; H10K 59/1201; H10K 59/124; H10K 59/131; H10K 59/38

(57) ABSTRACT

A display device, an electronic device including the display device, and a method for manufacturing the display device are disclosed. The display device may include: a substrate including a display area and a peripheral area around at least a portion of the display area, a common voltage supply line provided in the peripheral area and configured to have a common voltage applied to it, a support provided in the peripheral area and including a first insulating pattern, a second insulating pattern on the first insulating pattern, and a conductive pattern between the first insulating pattern and the second insulating pattern, at least one dam provided between the support and the display area in a plan view and around the display area, and a light emitting element including a pixel electrode, a light emitting layer, and a common electrode that are sequentially provided in the display area on the substrate.

### CROSS-REFERENCE TO RELATED APPLICATION

The present application claims priority to and benefit of Korean Patent Application No. 10-2024-0093612, filed on Jul. 16, 2024, in the Korean Intellectual Property Office, the entire content of which is incorporated herein by reference.

### BACKGROUND

### 1. Field

One or more embodiments of the present disclosure relate to display devices, electronic devices incorporating such display devices, and methods for manufacturing these display devices. For example, one or more embodiments of the present disclosure relate to display devices that provide visual information, electronic devices that include these display devices, and the methods for their manufacture.

### 2. Description of the Related Art

With the advancement of information technology, the significance of display devices as communication media between users and information has become increasingly prominent. Consequently, the use of one or more suitable types of display devices, including liquid crystal displays (LCDs), organic light-emitting diode (OLED) displays, and/or plasma displays, among others, is on the rise.

### SUMMARY

One or more aspects of embodiments of the present disclosure are directed toward a display device with reduced reliability defects (e.g., reduced structural defects).

One or more aspects of embodiments of the present disclosure are directed toward an electronic device including the display device.

One or more aspects of embodiments of the present disclosure are directed toward a method for manufacturing the display device.

Additional aspects of embodiments will be set forth in part in the description which follows and, in part, will be apparent from the description or may be learned by practice of the presented embodiments of the disclosure.

A display device according to one or more embodiments of the present disclosure includes a substrate including a display area and a peripheral area around (e.g., surrounding) at least a portion of the display area, a common voltage supply line located or provided in the peripheral area and configured to have a common voltage applied to it, a support located or provided in the peripheral area and including a first insulating (e.g., electrically insulating or insulator) pattern, a second insulating (e.g., electrically insulating or insulator) pattern on the first insulating pattern, and a conductive (e.g., electrically conductive or conductor) pattern between the first insulating pattern and the second insulating pattern, at least one dam located or provided between the support and the display area in a plan view and around (e.g., surrounding) the display area, and a light emitting element including a pixel electrode, a light emitting layer, and a common electrode that are sequentially located or provided in the display area on the substrate.

In one or more embodiments, the conductive pattern may include (e.g., may be) substantially the same material as the pixel electrode.

In one or more embodiments, the conductive pattern may be electrically connected to the common voltage supply line.

In one or more embodiments, the peripheral area may include a pad area where a pad electrode is located or provided, and at a bottom of the peripheral area adjacent to the pad area, the conductive pattern may contact the common voltage supply line through a contact hole.

In one or more embodiments, the conductive pattern may be a floating electrode.

In one or more embodiments, a direct current (DC) voltage may be applied to the conductive pattern. For example, the conductive pattern may be configured or arranged to have a direct current (DC) voltage applied to it.

In one or more embodiments, a thickness of the first insulating pattern may be greater than a thickness of the second insulating pattern.

In one or more embodiments, the first insulating pattern may include a lower portion having a first width and an upper portion having a second width that is smaller than the first width.

In one or more embodiments, the conducive pattern may contact an upper surface and a side surface of the upper portion of the first insulating pattern.

In one or more embodiments, the display device may further include an inorganic insulating (e.g., electrically insulating) layer on the substrate, an organic insulating (e.g., electrically insulating) layer on the inorganic insulating layer, and a pixel defining layer located or provided on the organic insulating layer and defining a pixel opening that exposes at least a portion of the pixel electrode, wherein the first insulating pattern may include substantially the same material as the organic insulating layer and the second insulating pattern may include substantially the same material as the pixel defining layer.

In one or more embodiments, the at least one dam may include a first dam including substantially the same material as the organic insulating layer, a second dam including: a first lower dam including substantially the same material as the organic insulating layer and a first upper dam located or provided on the first lower dam and including substantially the same material as the pixel defining layer, and located or provided outside of the first dam, and a third dam including: a second lower dam including substantially the same material as the organic insulating layer and a second upper dam located or provided on the second lower dam and including substantially the same material as the pixel defining layer, and located or provided outside of the second dam.

In one or more embodiments, the display device may further include a scan driver located or provided in the peripheral area and configured to provide a scan signal to a plurality of pixels in the display area and a line part located or provided outside the scan driver in the peripheral area and configured to provide a control signal to the scan driver. The support may at least partially overlap the line part in the plan view.

In one or more embodiments, the display device may further include a color conversion layer located or provided on the light emitting element and configured to convert a wavelength of light emitted from the light emitting layer and a color filter layer on the color conversion layer.

In one or more embodiments, the display device may further include a sealing member outside the support in the peripheral area.

A method for manufacturing a display device according to one or more embodiments of the present disclosure may include: forming or providing (e.g., applying) a support including a first insulating (e.g., electrically insulating) pattern, a second insulating (e.g., electrically insulating) pattern on the first insulating pattern, and a conductive (e.g., electrically conductive) pattern between the first insulating pattern and the second insulating pattern in a peripheral area on a substrate, wherein the substrate includes a display area and the peripheral area around (e.g., surrounding) at least a portion of the display area; forming or providing (e.g., applying) at least one dam between the support and the display area in a plan view and around (e.g., surrounding) the display area; forming or providing (e.g., applying) a common voltage supply line which is to receive a common voltage in the peripheral area; and forming or providing (e.g., applying) a light emitting element including a pixel electrode, a light emitting layer, and a common electrode that are sequentially formed or provided in the display area on the substrate.

In one or more embodiments, the forming or providing (e.g., applying) of the support may include forming or providing (e.g., applying) a preliminary organic insulating layer in the display area and the peripheral area on the substrate; exposing and developing the preliminary organic insulating layer through a halftone mask including a light transmission portion, a light blocking portion, and a semi-transmission portion, to remove a first portion of the preliminary organic insulating layer that corresponds to the semi-transmission portion in the peripheral area and leaving a second portion of the preliminary organic insulating layer that corresponds to the light transmission portion or the light blocking portion to form or provide a preliminary first insulating pattern; and forming or providing (e.g., applying) the conductive pattern that covers the preliminary first insulating pattern.

In one or more embodiments, after the forming or providing (e.g., applying) of the conductive pattern that covers the preliminary first insulating pattern, the forming or providing (e.g., applying) of the support may further include removing the first portion of the preliminary organic insulating layer in the peripheral area through an ashing process to form or provide an organic insulating (e.g., electrically insulating) layer and the first insulating pattern, with the organic insulating layer entirely (e.g., substantially entirely) in the display area and in a portion of the peripheral area.

In one or more embodiments, after the forming or providing (e.g., applying) of the first insulating pattern, the method may further include forming or providing (e.g., applying) a pixel defining layer that defines a pixel opening that exposes at least a portion of the pixel electrode on the organic insulating layer. The second insulating pattern may be formed or provided through substantially the same process as the pixel defining layer.

In one or more embodiments, the conductive pattern may be formed or provided through substantially the same process as the pixel electrode.

In one or more embodiments, the conductive pattern may be electrically connected to the common voltage supply line.

An electronic device according to one or more embodiments of the present disclosure includes a display device including: a substrate including a display area and a peripheral area around (e.g., surrounding) at least a portion of the display area; a common voltage supply line located or provided in the peripheral area and configured to have a common voltage applied to it; a support located or provided in the peripheral area and including a first insulating (e.g., electrically insulating) pattern, a second insulating (e.g., electrically insulating) pattern located or provided on the first insulating pattern, and a conductive (e.g., electrically conductive) pattern between the first insulating pattern and the second insulating pattern; at least one dam located or provided between the support and the display area in a plan view and around (e.g., surrounding) the display area; and a light emitting element including a pixel electrode, a light emitting layer, and a common electrode that are sequentially located or provided in the display area on the substrate, and a processor which is to control the display device by providing an image data signal and an input control signal to the display device.

In a display device according to one or more embodiments of the present disclosure, a support arranged or provided in a peripheral area and supporting a mask used during the mask process may include a first insulating (e.g., electrically insulating) pattern, a second insulating (e.g., electrically insulating) pattern on the first insulating pattern, and a conductive (e.g., electrically conductive) pattern between the first insulating pattern and the second insulating pattern. Accordingly, the conductive pattern may prevent or protect the first insulating pattern of the support from being damaged (or reduce a degree to or occurrence of which the first insulating pattern of the support is damaged) due to an ashing process for a via insulating (e.g., electrically insulating) layer. Accordingly, damages (or a degree or occurrence of damages) to a scan driver due to moisture penetration may be minimized or reduced. For example, the conductive pattern may act or serve to prevent or protect the first insulating pattern of the support from being damaged or reduce the degree or occurrence of damage, due to an ashing process for a via insulating (e.g., electrically insulating) layer. Consequently, damages, or the degree or occurrence of damages, to a scan driver due to moisture penetration may be minimized or reduced. This configuration or arrangement enhances the overall reliability and longevity of the display device by mitigating potential structural defects and ensuring stable operation under one or more environmental conditions.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of subject matter of the present disclosure.

FIG. 1 is a perspective view illustrating a display device according to one or more embodiments of the present disclosure.

FIG. 2 is a plan view illustrating the display device of FIG. 1.

FIG. 3 is an equivalent circuit diagram illustrating one pixel of FIG. 2.

FIG. 4 is a cross-sectional view taken along the line I-I′ of FIG. 3.

FIG. 5 is a cross-sectional view illustrating a first color conversion layer, a second color conversion layer, and a light transmission layer of FIG. 4.

FIG. 6 is a cross-sectional view taken along the line II-II′ of FIG. 3.

FIG. 7 is an enlarged cross-sectional view of area A of FIG. 6.

FIG. 8 is an enlarged plan view of a portion of a peripheral area of FIG. 2.

FIG. 9 is a cross-sectional view taken along the line III-III′ of FIG. 8.

FIGS. 10-23 are cross-sectional views illustrating one or more steps (e.g., acts or tasks) of a method for manufacturing the display device of FIGS. 4 and 6.

FIG. 24 is a block diagram illustrating an electronic device according to one or more embodiments of the present disclosure.

FIG. 25 are schematic diagrams illustrating an electronic device according to one or more suitable embodiments.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a layer is referred to as being “on” another layer or substrate, it may be directly on the other layer or substrate, or intervening layers may also be present therebetween. In contrast, if (e.g., when) a layer is referred to as being “directly on” another layer or substrate, there may be no intervening layers present therebetween.

The same reference numbers indicate substantially the same components throughout the specification.

In the attached drawings, the thickness of layers and regions may be exaggerated to effectively or suitably illustrate the technical contents of the present disclosure.

Although the terms “first,” “second,” and/or the like may be used herein to describe one or more suitable elements, these elements should not be limited by these terms. These terms may be used to distinguish one element from another element. Thus, a first element discussed herein may be termed a second element without departing from teachings of one or more embodiments. The description of an element as a “first” element may not require or imply the presence of a second element or other elements. The terms “first,” “second,” and/or the like may also be used herein to differentiate different categories or sets of elements. For conciseness, the terms “first,” “second,” and/or the like may represent “first-category (or first-set),” “second-category (or second-set),” and/or the like, respectively.

The utilization of “may,” if (e.g., when) describing embodiments of the present disclosure, refers to “one or more embodiments of the present disclosure.”

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein, is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

In the context of the present disclosure and unless otherwise defined, the terms “use,” “using,” and “used” may be considered synonymous with the terms “utilize,” “utilizing,” and “utilized,” respectively.

The aspects and features of one or more embodiments of the present disclosure may be combined partially or totally.

As will be clearly appreciated by those skilled in the art, technically one or more suitable interactions and operations may be possible. One or more embodiments may be practiced individually or in combination.

Hereinafter, a display device, an electronic device including the display device, and a method for manufacturing the display device according to one or more embodiments of the present disclosure will be described in more detail with reference to the accompanying drawings. The same reference numerals are used for substantially the same components in the drawings, and redundant descriptions of substantially the same components may not be provided.

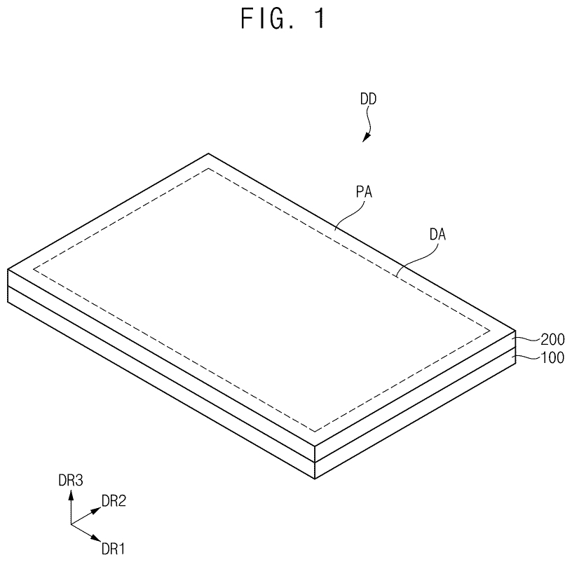

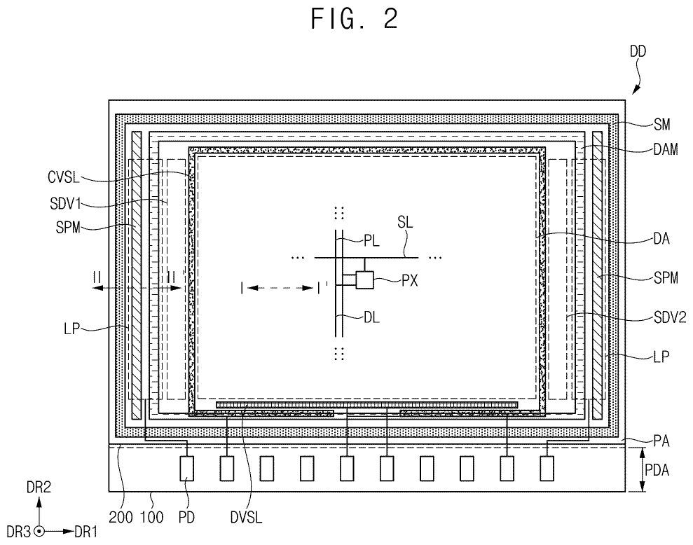

FIG. 1 is a perspective view illustrating a display device according to one or more embodiments of the present disclosure. FIG. 2 is a plan view illustrating the display device of FIG. 1.

Referring to FIGS. 1 and 2, the display device DD according to one or more embodiments of the present disclosure may be divided into a display area DA and a peripheral area PA. The display area DA may be an area to generate light or display an image by adjusting the transmittance of light provided from an external light source. The peripheral area PA may be around (e.g., surround) the display area DA. For example, the peripheral area PA may be around (e.g., surround) at least a portion of the display area DA. In one or more embodiments, the peripheral area PA may be an area that does not display an image. However, embodiments of the present disclosure are not necessarily limited thereto, and an image may be displayed in at least part of the peripheral area PA. For example, a light emitting element to emit light may be in at least a portion of the peripheral area PA.

A plurality of pixels PX may be in the display area DA. Each of the plurality of pixels PX may include a driving transistor and a light emitting element electrically connected to the driving transistor to generate light. The display area DA may be to display an image through the plurality of pixels PX. For example, the plurality of pixels PX may each be to emit red, green, or blue light. In one or more embodiments, the plurality of pixels PX may be in a matrix form along a first direction DR1 and a second direction DR2 that crosses (e.g., intersects) the first direction DR1.

The display device DD may include a lower structure 100 and an upper structure 200 on the lower structure 100 in a third direction DR3. The lower structure 100 may include the plurality of pixels PX, and the upper structure 200 may include a color conversion layer which is to convert the wavelength of light emitted by the plurality of pixels PX.

The lower structure 100 of the display device DD may include a pad electrode PD, a first scan driver SDV1, a second scan driver SDV2, a line part LP, a driving voltage supply line DVSL, a common voltage supply line CVSL, a scan line SL, a data line DL, a driving voltage line PL, a dam DAM, a support SPM, and a sealing member SM.

The first scan driver SDV1 may be in the peripheral area PA adjacent to a left edge of the display area DA. The first scan driver SDV1 may include at least one driver transistor. In one or more embodiments, the line part LP including control signal lines which are to transmit control signals to drive the first scan driver SDV1 may be outside the first scan driver SDV1. The line part LP may be to receive a first control signal from the pad electrode PD and transmit the first control signal to the first scan driver SDV1. The first scan driver SDV1 may be to generate a first scan signal based on the first control signal.

The second scan driver SDV2 may be in the peripheral area PA adjacent to a right edge of the display area DA. The second scan driver SDV2 may include at least one driver transistor. In one or more embodiments, the line part LP including control signal lines that are to transmit control signals to drive the second scan driver SDV2 may be outside the second scan driver SDV2. The line part LP may be to receive a second control signal from the pad electrode PD and transmit the second control signal to the second scan driver SDV2. The second scan driver SDV2 may be to generate a second scan signal based on the second control signal.

However, embodiments of the present disclosure are not necessarily limited thereto, and either the first scan driver SDV1 or the second scan driver SDV2 may not be provided.

The data line DL, the driving voltage line PL, and the scan line SL may be arranged or provided in the display area DA and electrically connected to the plurality of pixels PX. In one or more embodiments, the driving voltage supply line DVSL and the common voltage supply line CVSL may be arranged or provided in the peripheral area PA and electrically connected to the pad electrode PD.

The scan line SL may be electrically connected to the first scan driver SDV1 and the second driver SDV2 and extend in the first direction DR1. The scan line SL may be to receive the first scan signal from the first scan driver SDV1 and provide the first scan signal to the plurality of pixels PX. Likewise, the scan line SL may be to receive the second scan signal from the second scan driver SDV2 and provide the second scan signal to the plurality of pixels PX.

The data line DL may be electrically connected to the pad electrode PD and extend in the second direction DR2. The data line DL may be to receive a data voltage from the pad electrode PD and provide the data voltage to the plurality of pixels PX.

The driving voltage supply line DVSL may be between the pad electrode PD and the display area DA in a plan view. The driving voltage supply line DVSL may be electrically connected to the pad electrode PD and the driving voltage line PL. The driving voltage supply line DVSL may be to receive the driving voltage from the pad electrode PD and provide the driving voltage to the driving voltage line PL.

The driving voltage line PL may extend along the second direction DR2. The driving voltage line PL may be to provide the driving voltage to the plurality of pixels PX.

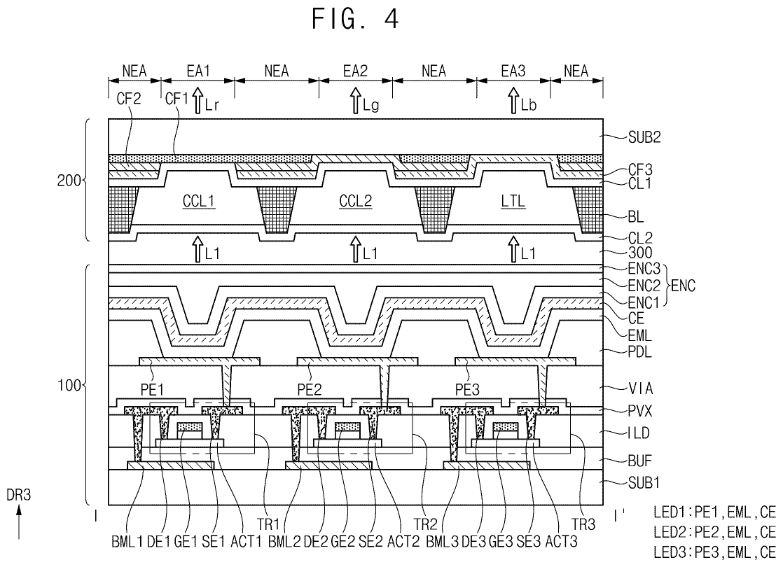

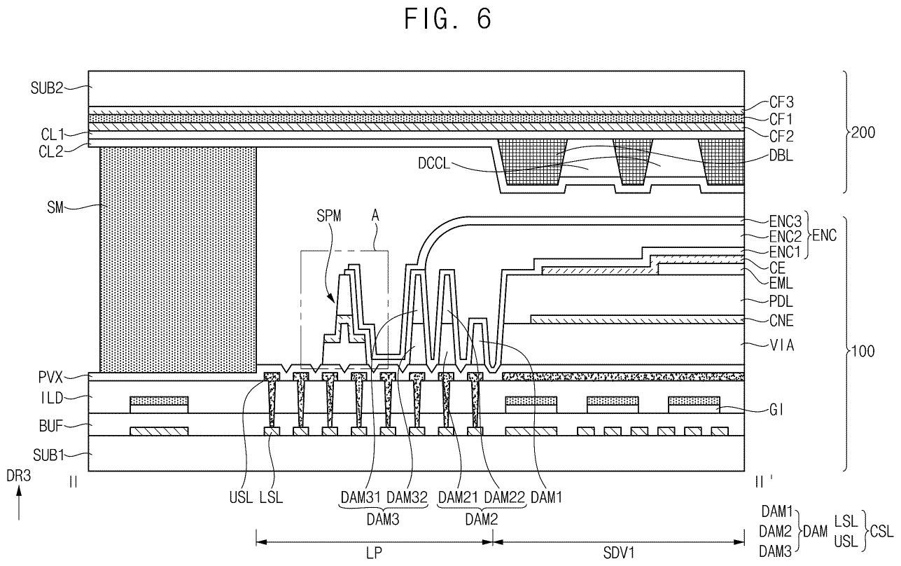

The common voltage supply line CVSL may be around (e.g., surround) at least a portion of the display area DA. For example, the common voltage supply line CVSL may include a first portion that extends in the second direction DR2 and that is at a left edge of the peripheral area PA, a second portion that extends from the first portion in the first direction DR1 and that is at an upper edge of the peripheral area PA, and a third portion that extends from the second portion in the second direction DR2 and that is at a right edge of the peripheral area PA. The common voltage supply line CVSL may be electrically connected to the pad electrode PD and the common electrode CE. The common voltage supply line CVSL may be to receive the common voltage from the pad electrode PD and provide the common voltage to a common electrode (e.g., a common electrode CE of FIGS. 4 and 6).

The dam DAM may be in the peripheral area PA. The dam DAM may be around (e.g., surround) at least a portion of the display area DA. For example, the dam DAM may entirely (e.g., substantially entirely) be around (e.g., surround) the display area DA. The dam DAM may be to control an organic encapsulation layer (e.g., an organic encapsulation layer ENC2 of FIGS. 4 and 6). Accordingly, a path through which moisture from the outside penetrates into the display area DA through the organic encapsulation layer may be blocked (or a degree to or occurrence of which moisture from the outside penetrates into the display area DA through the organic encapsulation layer may be reduced). For example, the dam DAM may include an organic material.

For example, the dam DAM may at least partially overlap the line part LP in the plan view. For example, the dam DAM may be between the support SPM and the first scan driver SDV1 in the plan view and may be between the support SPM and the second scan driver SDV2. In one or more embodiments, the dam DAM may at least partially overlap the first scan driver SDV1 and the second scan driver SDV2 in the plan view. In one or more embodiments, the dam DAM may at least partially overlap the line part LP, the first scan driver SDV1, and the second scan driver SDV2 in the plan view.

The number of dams DAM may vary. For example, the number of dam DAM may be three. However, embodiments of the present disclosure are not necessarily limited thereto.

The support SPM may be in the peripheral area PA. The support SPM may be on the outside of the dam DAM. For example, the support SPM may be on the left edge and the right edge of the dam DAM. However, embodiments of the present disclosure are not necessarily limited thereto, and the support SPM may be around (e.g., surround) at least a portion of the dam DAM in the plan view. The support SPM may be a member to support a mask (e.g., an open mask used in a process to form or provide a light emitting layer EML, the common electrode CE, and an encapsulation layer ENC) used during a mask process. For example, the support SPM may include an organic material.

For example, the support SPM may at least partially overlap the line part LP in the plan view.

The sealing member SM may be in the peripheral area PA. The sealing member SM may be on the outside of the support SPM. The sealing member SM may be around (e.g., surround) the dam DAM and the support SPM in the plan view. The sealing member SM may seal the display area DA from external air by coupling the lower structure 100 and the upper structure 200 between the lower structure 100 and the upper structure 200. For example, the sealing member SM may include an organic material.

For example, the sealing member SM may at least partially overlap the line part LP in the plan view. However, embodiments of the present disclosure are not necessarily limited thereto, and the sealing member SM may not overlap the line part LP in the plan view.

The peripheral area PA may include a pad area PDA at a bottom of the display area DA. The pad area PDA may have a shape that extends in the first direction DR1. The pad electrode PD may be in the pad area PDA. For example, a plurality of pad electrodes PD may be provided repeatedly along the first direction DR1.

A driving chip and/or a printed circuit board may be electrically connected to the pad electrode PD. The driving chip may include an integrated circuit (IC). Accordingly, the lower structure 100 and the driving chip and/or the printed circuit board may be electrically connected through the pad electrode PD. The pad electrode PD may be to receive one or more suitable signals, voltages, and/or the like necessary to drive the display device DD through the driving chip and/or the printed circuit board.

In one or more embodiments, a plane may be defined in the first direction DR1 and the second direction DR2. For example, the first direction DR1 may be normal (e.g., perpendicular) to the second direction DR2. In one or more embodiments, the third direction DR3 may be normal (e.g., perpendicular) to the plane.

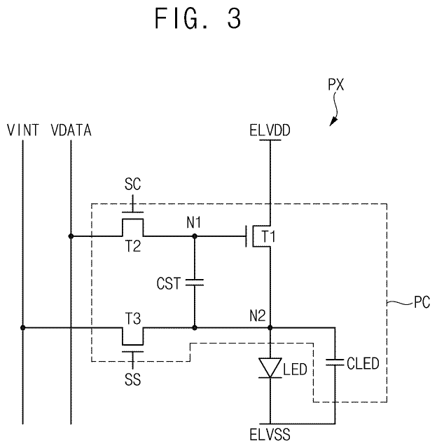

FIG. 3 is an equivalent circuit diagram illustrating one pixel of FIG. 2.

Referring to FIG. 3, one pixel PX may include a pixel driving circuit part PC and a light emitting element LED electrically connected to the pixel driving circuit part PC. The pixel driving circuit part PC may be to generate a driving current, and the light emitting element LED may be to generate light based on the driving current.

The pixel driving circuit part PC may include a first transistor T1, a second transistor T2, a third transistor T3, a storage capacitor CST, and a light emitting capacitor CLED.

The first transistor T1 may include a first electrode, a gate electrode, and a second electrode. The gate electrode of the first transistor T1 may be connected to a first node N1. A driving voltage ELVDD may be applied to the second electrode of the first transistor T1. The first electrode of the first transistor T1 may be connected to a second node N2. The first transistor T1 may be to receive the driving voltage ELVDD from a driving voltage line in response to the voltage of the first node N1 and supply the driving current to the light emitting element LED. For example, the first transistor T1 may be a driving transistor to drive the light emitting element LED.

The second transistor T2 may include a first electrode, a gate electrode, and a second electrode. A first scan signal SC may be applied to the gate electrode of the second transistor T2. A data voltage VDATA may be applied to the second electrode of the second transistor T2. The first electrode of the second transistor T2 may be connected to the first node N1. The second transistor T2 may be turned on by the first scan signal SC to electrically connect a data line which is to provide the data voltage VDATA to the first node N1. For example, the second transistor T2 may be a switching transistor.

The third transistor T3 may include a first electrode, a gate electrode, and a second electrode. A second scan signal SS may be applied to the gate electrode of the third transistor T3. An initialization voltage VINT may be applied to the second electrode of the third transistor T3. The first electrode of the third transistor T3 may be connected to the second node N2. The third transistor T3 may be turned on by the second scan signal SS to electrically connect an initialization voltage line which is to provide the initialization voltage VINT to the second node N2. For example, the third transistor T3 may be an initialization transistor.

In one or more embodiments, the first transistor T1, the second transistor T2, and the third transistor T3 may all be NMOS transistors (or nMOS transistors or negative (N)-type (kind) metal-oxide-semiconductor transistors). However, embodiments of the present disclosure are not necessarily limited thereto, and the first transistor T1, the second transistor T2, and the third transistor T3 may all be PMOS transistors (or pMOS transistors or positive (P)-type (kind) metal-oxide-semiconductor transistors), or at least one may be an NMOS transistor, and the remainder may be PMOS transistors.

If (e.g., when) the pixel driving circuit part PC includes an NMOS transistor and a PMOS transistor, an active pattern of the NMOS transistor may include a metal oxide semiconductor, and an active pattern of the PMOS transistor may include a silicon semiconductor. However, embodiments of the present disclosure are not necessarily limited thereto, and the active pattern of the NMOS transistor may include a silicon semiconductor, and the active pattern of the PMOS transistor may include a metal oxide semiconductor.

In one or more embodiments, the first electrode of each of the first transistor T1, the second transistor T2, and the third transistor T3 may be a source electrode, and the second electrode of each of the first transistor T1, the second transistor T2, and the third transistor T3 may be a drain electrode. However, embodiments of the present disclosure are not necessarily limited thereto, and the first electrode of each of the first transistor T1, the second transistor T2, and the third transistor T3 may be a drain electrode, and the second electrode of each of the first transistor T1, the second transistor T2, and the third transistor T3 may be a source electrode.

The storage capacitor CST may include a first electrode and a second electrode. The first electrode of the storage capacitor CST may be connected to the first node N1. The second electrode of the storage capacitor CST may be connected to the second node N2. The storage capacitor CST may be to store a difference voltage between a gate voltage and a source voltage of the first transistor T1.

The light emitting capacitor CLED may include a first electrode and a second electrode. The first electrode of the light emitting capacitor CLED may be connected to the second node N2. The second electrode of the light emitting capacitor CLED may be connected to the second electrode of the light emitting element LED. The light emitting capacitor CLED may be to maintain or provide the voltage across both (e.g., simultaneously) ends of the light emitting element LED constant (e.g., substantially constant), thereby enabling the light emitting element LED to display constant (e.g., substantially constant) luminance. In one or more embodiments, the light emitting capacitor CLED may not be provided.

The light emitting element LED may include a first electrode (e.g., anode electrode) and a second electrode (e.g., cathode electrode). The first electrode of the light emitting element LED may be connected to the second node N2. A common voltage ELVSS may be applied to the second electrode of the light emitting element LED. The light emitting element LED may be to emit light with a luminance that corresponds to the driving current provided from the pixel driving circuit part PC.

However, in FIG. 2, one pixel PX is illustrated as including three transistors T1, T2, and T3, one storage capacitor CST, and one light emitting capacitor CLED, but embodiments of the present disclosure are not necessarily limited thereto.

In one or more embodiments, in FIG. 2, one pixel PX is illustrated as including one light emitting element LED, but embodiments of the present disclosure are not necessarily limited thereto. For example, one pixel PX may include two or more light emitting elements.

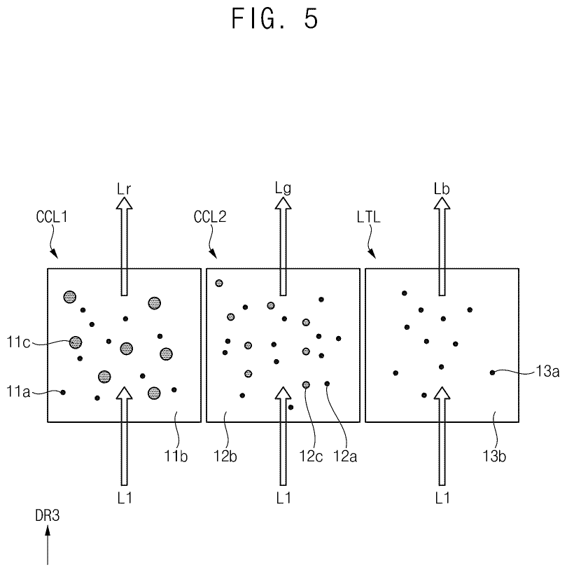

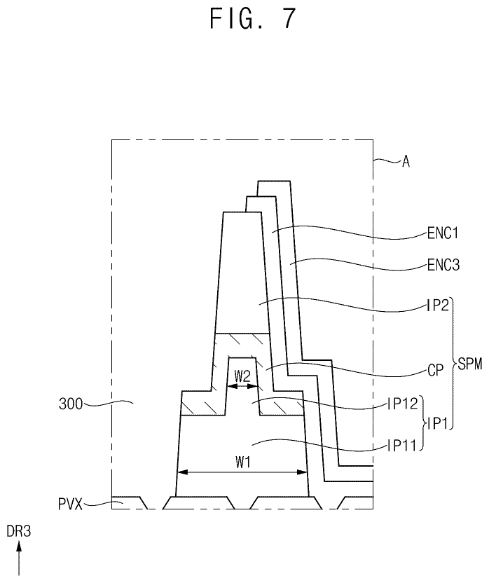

FIG. 4 is a cross-sectional view taken along the line I-I′ of FIG. 3. FIG. 5 is a cross-sectional view illustrating a first color conversion layer, a second color conversion layer, and a light transmission layer of FIG. 4. FIG. 6 is a cross-sectional view taken along the line II-II′ of FIG. 3. FIG. 7 is an enlarged cross-sectional view of area A of FIG. 6.

Referring to FIGS. 2, 4, 5, 6, and 7, the display device DD may include the lower structure 100, the upper structure 200 on the lower structure 100, and a filling layer 300 between the lower structure 100 and the upper structure 200. First, the components of the lower structure 100 will be described herein in more detail.

The lower structure 100 may include a first substrate SUB1, a first lower conductive layer BML1, a second lower conductive layer BML2, a third lower conductive layer BML3, a buffer layer BUF, a gate insulating layer GI, a first transistor TR1, a second transistor TR2, a third transistor TR3, an interlayer insulating layer ILD, a passivation layer PVX, a via insulating layer VIA, a pixel defining layer PDL, a first light emitting element LED1, a second light emitting element LED2, a third light emitting element LED3, an encapsulation layer ENC, the first scan driver SDV1, the line part LP, the dam DAM, the support SPM, and a connection pattern CNE.

In one or more embodiments, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

The first light emitting element LED1 may include a first pixel electrode PE1, a light emitting layer EML, and the common electrode CE, and the second light emitting element LED2 may include a second pixel electrode PE2, the light emitting layer EML, and the common electrode CE, and the third light emitting element LED3 may include a third pixel electrode PE3, the light emitting layer EML, and the common electrode CE. In one or more embodiments, the line part LP may include a control signal line CSL including a lower signal line LSL and an upper signal line USL.

As described in one or more embodiments, the display device DD may be divided into the display area DA and the peripheral area PA. Accordingly, the first substrate SUB1 included in the display device DD may include the display area DA and the peripheral area PA.

The display area DA may include a first light emitting area EA1, a second light emitting area EA2, a third light emitting area EA3, and a non-light emitting area NEA. One pixel PX of FIG. 2 may be in the first light emitting area EA1, the second light emitting area EA2, and the third light emitting area EA3, respectively. Accordingly, each of the first light emitting area EA1, the second light emitting area EA2, and the third light emitting area EA3 may be to emit light through the one pixel PX.

For example, the first light emitting area EA1 may be to emit light Lr of a first color, the second light emitting area EA2 may be to emit light Lg of a second color, and the third light emitting area EA3 may be to emit light Lb of a third color. In one or more embodiments, the first color may be red, the second color may be green, and the third color may be blue. However, embodiments of the present disclosure are not necessarily limited thereto.

The non-light emitting area NEA may be between the first light emitting area EA1, the second light emitting area EA2, and the third light emitting area EA3 and may be an area that does not emit light.

The first substrate SUB1 may include a transparent (e.g., substantially transparent) material and/or an opaque material. The first substrate SUB1 may be made of a transparent (e.g., substantially transparent) resin substrate. Examples of the transparent resin substrate may include a polyimide substrate. In one or more embodiments, the polyimide substrate may include a first organic layer, a first barrier layer, a second organic layer, and/or the like. In one or more embodiments, the first substrate SUB1 may include a natural quartz substrate, a synthetic quartz substrate, a calcium fluoride substrate, a F-doped quartz substrate, a soda-lime glass substrate, a non-alkali glass substrate, and/or the like. These substrates may be used alone or in combination with each other.

The first lower conductive layer BML1, the second lower conductive layer BML2, and the third lower conductive layer BML3 may be in the display area DA on the first substrate SUB1. The first lower conductive layer BML1, the second lower conductive layer BML2, and the third lower conductive layer BML3 may be connected to the first transistor TR1, the second transistor TR2, and the third transistor TR3, respectively. The first lower conductive layer BML1, the second lower conductive layer BML2, and the third lower conductive layer BML3 may be to block external light incident on the first transistor TR1, the second transistor TR2, and the third transistor TR3. In one or more embodiments, the first lower conductive layer BML1, the second lower conductive layer BML2, and the third lower conductive layer BML3 may be to transmit signals and/or voltages to the first transistor TR1, the second transistor TR2, and the third transistor TR3. For example, the first lower conductive layer BML1, the second lower conductive layer BML2, and the third lower conductive layer BML3 may include metal, alloy, metal nitride, conductive (e.g., electrically conductive) metal oxide, transparent (e.g., substantially transparent) conductive (e.g., electrically conductive) material, and/or the like. These materials may be used alone or in combination with each other.

The first lower conductive layer BML1, the second lower conductive layer BML2, and the third lower conductive layer BML3 may be in substantially the same layer. In one or more embodiments, the first lower conductive layer BML1, the second lower conductive layer BML2, and the third lower conductive layer BML3 may be formed or provided through substantially the same process and may include substantially the same material.

At least one lower signal line LSL may be in the peripheral area PA on the first substrate SUB1. The lower signal line LSL may be formed or provided through substantially the same process as the first lower conductive layer BML1, the second lower conductive layer BML2, and the third lower conductive layer BML3 and may include (e.g., may be) substantially the same material.

The buffer layer BUF may be on the first substrate SUB1. The buffer layer BUF may be arranged or provided entirely (e.g., substantially entirely) in the display area DA and the peripheral area PA. The buffer layer BUF may prevent metal atoms and/or impurities from diffusing from the first substrate SUB1 to the first transistor TR1, the second transistor TR2, and the third transistor TR3 (or reduce a degree to or occurrence of which metal atoms and/or impurities diffuse from the first substrate SUB1 to the first transistor TR1, the second transistor TR2, and the third transistor TR3). In one or more embodiments, the buffer layer BUF may improve or enhance the flatness of the surface of the first substrate SUB1 if (e.g., when) the surface of the first substrate SUB1 is not substantially uniform. For example, the buffer layer BUF may include an inorganic material, such as silicon oxide (e.g., SiOₓ, wherein 0<X≤2; e.g., SiO₂), silicon nitride (e.g., SiNₓ, wherein 0<X≤2, e.g., Si₃N₄), silicon oxynitride (e.g., Si₂N₂O or SiOₓN_{y}, wherein 0<X≤2 and 0≤Y≤2; e.g., SiON), and/or the like. These materials may be used alone or in combination with each other.

The first active pattern ACT1, the second active pattern ACT2, and the third active pattern ACT3 may be in the display area DA on the buffer layer BUF. In one or more embodiments, each of the first active pattern ACT1, the second active pattern ACT2, and the third active pattern ACT3 may include a metal oxide semiconductor. The metal oxide semiconductor may a binary compound (ABₓ), a ternary compound (ABₓC_{y}), a quaternary compound (ABₓC_{y}D_{z}), and/or the like containing indium (In), zinc (Zn), gallium (Ga), tin (Sn), titanium (Ti), aluminum (Al), hafnium (Hf), zirconium (Zr), magnesium (Mg), and/or the like. For example, the metal oxide semiconductor may include zinc oxide (ZnOₓ) (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and/or the like. These materials may be used alone or in combination with each other.

However, embodiments of the present disclosure are not necessarily limited thereto, and each of the first active pattern ACT1, the second active pattern ACT2, and the third active pattern ACT3 may include a silicon semiconductor (e.g., polysilicon).

Each of the first active pattern ACT1, the second active pattern ACT2, and the third active pattern ACT3 may include a source region, a drain region, and a channel region between the source region and the drain region. For example, the source region and the drain region may be doped with impurities (e.g., negative (N)-type (kind) impurities and/or positive (P)-type (kind) impurities), and the channel region may not be doped with impurities.

The first active pattern ACT1, the second active pattern ACT2, and the third active pattern ACT3 may be in substantially the same layer. In one or more embodiments, the first active pattern ACT1, the second active pattern ACT2, and the third active pattern ACT3 may be formed or provided through substantially the same process and may include substantially the same material.

The gate insulating layer GI may be on the first active pattern ACT1, the second active pattern ACT2, and the third active pattern ACT3, respectively. The gate insulating layer GI may be patterned to overlap the channel region of each of the first active pattern ACT1, the second active pattern ACT2, and the third active pattern ACT3. The gate insulating layer GI may be patterned and arranged or provided in the peripheral area PA. In one or more embodiments, the gate insulating layer GI may sufficiently or suitably cover the first active pattern ACT1, the second active pattern ACT2, and the third active pattern ACT3 and may be arranged or provided entirely (e.g., substantially entirely) in the display area DA and the peripheral area PA. For example, the gate insulating layer GI may include an inorganic material, such as silicon oxide, silicon nitride, silicon oxynitride, and/or the like. These materials may be used alone or in combination with each other.

The first gate electrode GE1, the second gate electrode GE3, and the third gate electrode GE3 may be respectively arranged or provided on the gate insulating layer GI. The first gate electrode GE1, the second gate electrode GE3, and the third gate electrode GE3 may overlap the channel regions of the first active pattern ACT1, the second active pattern ACT2, and the third active pattern ACT3, respectively. For example, the first gate electrode GE1, the second gate electrode GE3, and the third gate electrode GE3 may include metal, alloy, metal nitride, conductive (e.g., electrically conductive) metal oxide, transparent (e.g., substantially transparent) conductive (e.g., electrically conductive) material, and/or the like. These materials may be used alone or in combination with each other.

The interlayer insulating layer ILD may be on the buffer layer BUF. The interlayer insulating layer ILD may be arranged or provided entirely (e.g., substantially entirely) in the display area DA and the peripheral area PA. The interlayer insulating layer ILD may cover the first gate electrode GE1, the second gate electrode GE3, and the third gate electrode GE3. For example, the interlayer insulating layer ILD may include an inorganic material, such as silicon oxide, silicon nitride, silicon oxynitride, and/or the like. These materials may be used alone or in combination with each other.

The first source electrode SE1, the second source electrode SE2, and the third source electrode SE3 may be in the display area DA on the interlayer insulating layer ILD. The first source electrode SE1 may be connected to the source region of the first active pattern ACT1 through a contact hole (e.g., via or opening) that penetrates the interlayer insulating layer ILD. The second source electrode SE2 may be connected to the source region of the second active pattern ACT2 through a contact hole that penetrates the interlayer insulating layer ILD. In one or more embodiments, the third source electrode SE3 may be connected to the source region of the third active pattern ACT3 through a contact hole that penetrates the interlayer insulating layer ILD.

The first drain electrode DE1, the second drain electrode DE2, and the third drain electrode DE3 may be in the display area DA on the interlayer insulating layer ILD. The first drain electrode DE1 may be connected to the drain region of the first active pattern ACT1 through a contact hole that penetrates the interlayer insulating layer ILD and may be connected to the first lower conductive layer BML1 through a contact hole that penetrates the buffer layer BUF and the interlayer insulating layer ILD. The second drain electrode DE2 may be connected to the drain region of the second active pattern ACT2 through a contact hole that penetrates the interlayer insulating layer ILD and may be connected to the second lower conductive layer BML2 through a contact hole that penetrates the buffer layer BUF and the interlayer insulating layer ILD. In one or more embodiments, the third drain electrode DE3 may be connected to the drain region of the third active pattern ACT3 through a contact hole that penetrates the interlayer insulating layer ILD and may be connected to the third lower conductive layer BML3 through a contact hole that penetrates the buffer layer BUF and the interlayer insulating layer ILD.

For example, the first source electrode SE1, the second source electrode SE2, the third source electrode SE3, the first drain electrode DE1, the second drain electrode DE2, and the third drain electrode DE3 may include metal, alloy, metal nitride, conductive (e.g., electrically conductive) metal oxide, transparent (e.g., substantially transparent) conductive (e.g., electrically conductive) material, and/or the like. These materials may be used alone or in combination with each other.

In one or more embodiments, each of the first source electrode SE1, the second source electrode SE2, the third source electrode SE3, the first drain electrode DE1, the second drain electrode DE2, and the third drain electrode DE3 may have a single-layer structure or a multi-layer structure including Ti/Al/Ti.

The first source electrode SE1, the second source electrode SE2, the third source electrode SE3, the first drain electrode DE1, the second drain electrode DE2, and the third drain electrode DE3 may be in substantially the same layer. In one or more embodiments, the first source electrode SE1, the second source electrode SE2, the third source electrode SE3, the first drain electrode DE1, the second drain electrode DE2, and the third drain electrode DE3 may be formed or provided through substantially the same process and may include substantially the same material.

At least one upper signal line USL may be in the peripheral area PA on the interlayer insulating layer ILD. The upper signal line USL may be connected to the lower signal line LSL through a contact hole that penetrates the buffer layer BUF and the interlayer insulating layer ILD. The upper signal line USL may be formed or provided through substantially the same process as the first source electrode SE1, the second source electrode SE2, the third source electrode SE3, the first drain electrode DE1, the second drain electrode DE2, and the third drain electrode DE3 and may include substantially the same material as the first source electrode SE1, the second source electrode SE2, the third source electrode SE3, the first drain electrode DE1, the second drain electrode DE2, and the third drain electrode DE3.

The passivation layer PVX may be on the first source electrode SE1, the second source electrode SE2, the third source electrode SE3, the first drain electrode DE1, the second drain electrode DE2, the third drain electrode DE3, and the upper signal line USL. The passivation layer PVX may be arranged or provided entirely (e.g., substantially entirely) in the display area DA and the peripheral area PA to cover the first source electrode SE1, the second source electrode SE2, the third source electrode SE3, the first drain electrode DE1, the second drain electrode DE2, the third drain electrode DE3, and the upper signal line USL.

For example, the passivation layer PVX may be along the profiles of each of the first source electrode SE1, the second source electrode SE2, the third source electrode SE3, the first drain electrode DE1, the second drain electrode DE2, the third drain electrode DE3, and the upper signal line USL with a substantially uniform thickness. However, embodiments of the present disclosure are not necessarily limited thereto.

For example, the passivation layer PVX may include an inorganic material, such as silicon oxide, silicon nitride, silicon oxynitride, and/or the like. These materials may be used alone or in combination with each other.

The via insulating layer VIA may be on the passivation layer PVX. The via insulating layer VIA may be arranged or provided entirely (e.g., substantially entirely) in the display area DA and may be arranged or provided in a portion of the peripheral area PA. For example, the via insulating layer VIA may not overlap the line part LP in the peripheral area PA. For example, the via insulating layer VIA may include an organic material, such as a photoresist, a polyacrylic resin, a polyimide resin, a polyamide resin, a siloxane resin, an acrylic resin, an epoxy resin, and/or the like. These materials may be used alone or in combination with each other.

In one or more embodiments, each of the buffer layer BUF, the interlayer insulating layer ILD, and the passivation layer PVX may be referred to as an inorganic insulating (e.g., electrically insulating) layer, and the via insulating layer VIA may be referred to as an organic insulating (e.g., electrically insulating) layer.

The first pixel electrode PE1, the second pixel electrode PE2, and the third pixel electrode PE3 may be in the display area DA on the via insulating layer VIA. The first pixel electrode PE1 may overlap the first light emitting area EA1, the second pixel electrode PE2 may overlap the second light emitting area EA2, and the third pixel electrode PE3 may overlap the third light emitting area EA3. The first pixel electrode PE1 may be connected to the first source electrode SE1 through a contact hole that penetrates the via insulating layer VIA and the passivation layer PVX. The second pixel electrode PE2 may be connected to the second source electrode SE2 through a contact hole that penetrates the via insulating layer VIA and the passivation layer PVX. In one or more embodiments, the third pixel electrode PE3 may be connected to the third source electrode SE3 through a contact hole that penetrates the via insulating layer VIA and the passivation layer PVX.

The first pixel electrode PE1, the second pixel electrode PE2, and the third pixel electrode PE3 may include reflective electrodes. For example, the first pixel electrode PE1, the second pixel electrode PE2, and the third pixel electrode PE3 may include metal, alloy, metal nitride, conductive (e.g., electrically conductive) metal oxide, transparent (e.g., substantially transparent) conductive (e.g., electrically conductive) material, and/or the like. These materials may be used alone or in combination with each other.

In one or more embodiments, each of the first pixel electrode PE1, the second pixel electrode PE2, and the third pixel electrode PE3 may have a three-layer structure including ITO/Ag/ITO. However, embodiments of the present disclosure are not necessarily limited thereto.

The first pixel electrode PE1, the second pixel electrode PE2, and the third pixel electrode PE3 may be in substantially the same layer. In one or more embodiments, the first pixel electrode PE1, the second pixel electrode PE2, and the third pixel electrode PE3 may be formed or provided through substantially the same process and may include substantially the same material.

The connection pattern CNE may be in the peripheral area PA on the via insulating layer VIA. The connection pattern CNE may be formed or provided through substantially the same process as the first pixel electrode PE1, the second pixel electrode PE2, and the third pixel electrode PE3 and may include substantially the same material as the first pixel electrode PE1, the second pixel electrode PE2, and the third pixel electrode PE3.

The pixel defining layer PDL may be on the via insulating layer VIA. The pixel defining layer PDL may be arranged or provided entirely (e.g., substantially entirely) in the display area DA and may be arranged or provided in a portion of the peripheral area PA. For example, the pixel defining layer PDL may not overlap the line part LP in the peripheral area PA.

A pixel opening that exposes at least a portion of an upper surface of each of the first pixel electrode PE1, the second pixel electrode PE2, and the third pixel electrode PE3 may be defined in the pixel defining layer PDL. The pixel defining layer PDL may include an organic material and/or an inorganic material. In one or more embodiments, the pixel defining layer PDL may include an organic material. For example, the pixel defining layer PDL may include a photoresist, a polyacrylic resin, a polyimide resin, a polyamide resin, a siloxane resin, an acrylic resin, an epoxy resin, and/or the like. These materials may be used alone or in combination with each other.

The light emitting layer EML may be on the pixel defining layer PDL, the first pixel electrode PE1, the second pixel electrode PE2, and the third pixel electrode PE3. In one or more embodiments, the light emitting layer EML may be in the pixel opening of the pixel defining layer PDL. For example, the light emitting layer EML may be arranged or provided entirely (e.g., substantially entirely) in the display area DA and may be arranged or provided in a portion of the peripheral area PA. The functional layers, such as an electron injection layer, an electron transport layer, a hole injection layer, and/or a hole transport layer, may be further arranged or provided on/under the light emitting layer EML.

In one or more embodiments, the light emitting layer EML may include a light emitting material which is to emit blue light L1. For example, the light emitting layer EML may have a single-layer structure including a blue light-emitting layer which is to emit blue light L1. In one or more embodiments, the light emitting layer EML may have a multi-layer structure including a plurality of light emitting layers. In one or more embodiments, the light emitting layer may include three blue light emitting layers or may include three blue light emitting layers and one green light emitting layer.

The common electrode CE may be on the light emitting layer EML. The common electrode CE may be arranged or provided entirely (e.g., substantially entirely) in the display area DA and may be arranged or provided in a portion of the peripheral area PA. For example, the common electrode CE may not overlap the line part LP in the peripheral area PA.

The common electrode CE may include a semi-transmissive or transmissive electrode. The common electrode CE may include a conductive (e.g., electrically conductive) material with a low work function. For example, the common electrode CE may include metal, alloy, metal nitride, conductive (e.g., electrically conductive) metal oxide, transparent (e.g., substantially transparent) conductive (e.g., electrically conductive) material, and/or the like. These materials may be used alone or in combination with each other.

As described in one or more embodiments, the dam DAM may be in the peripheral area PA. In one or more embodiments, the dam DAM may include a first dam DAM1, a second dam DAM2, and a third dam DAM3.

The first dam DAM1 may be outside the first scan driver SDV1. The first dam DAM1 may be around (e.g., surround) the display area DA. For example, the first dam DAM1 may be closer to the display area DA than the second dam DAM2 and the third dam DAM3. In one or more embodiments, the first dam DAM1 may be formed or provided through substantially the same process as the via insulating layer VIA and may include substantially the same material as the via insulating layer VIA.

The second dam DAM2 may be outside the first dam DAM1. The second dam DAM2 may be around (e.g., surround) the first dam DAM1. In one or more embodiments, the second dam DAM2 may have a two-layer structure including a first lower dam DAM21 and a first upper dam DAM22 on the first lower dam DAM21. The first lower dam DAM21 may be formed or provided through substantially the same process as the via insulating layer VIA and may include substantially the same material as the via insulating layer VIA. In one or more embodiments, the first upper dam DAM22 may be formed or provided through substantially the same process as the pixel defining layer PDL and may include substantially the same material as the pixel defining layer PDL.

The third dam DAM3 may be outside the second dam DAM2. The third dam DAM3 may be around (e.g., surround) the second dam DAM2. For example, the third dam DAM3 may be closer to an edge of the peripheral area PA than the first dam DAM1 and the second dam DAM2. In one or more embodiments, the third dam may include a second lower dam DAM31 and a second upper dam DAM32 on the second lower dam DAM31. The second lower dam DAM31 may be formed or provided through substantially the same process as the via insulating layer VIA and may include substantially the same material as the via insulating layer VIA. In one or more embodiments, the second upper dam DAM32 may be formed or provided through substantially the same process as the pixel defining layer PDL and may include substantially the same material as the pixel defining layer PDL.

For example, the first dam DAM1, the second dam DAM2, and the third dam DAM3 may at least partially overlap the control signal line CSL (e.g., the line part LP) in the plan view. In one or more embodiments, the first dam DAM1, the second dam DAM2, and the third dam DAM3 may not overlap the control signal line CSL (e.g., the line part LP) in the plan view. For example, the control signal line CSL may not be arranged or provided directly under the first dam DAM1, the second dam DAM2, and the third dam DAM3.

In one or more embodiments, the support SPM may include a first insulating pattern IP1, a second insulating pattern IP2 on the first insulating pattern IP1, and a conductive pattern CP between the first insulating pattern IP1 and the second insulating pattern IP2.

The conductive pattern CP may prevent the first insulating pattern IP1 of the support SPM from being damaged (or reduce a degree to or occurrence of which the first insulating pattern IP1 of the support SPM is damaged) due to an ashing process for the via insulating layer VIA. Accordingly, a degree or occurrence of damages to the scan driver (e.g., the first scan driver SDV1 and the second scan driver SDV2 of FIG. 2) due to moisture penetration may be minimized or reduced.

The first insulating pattern IP1 may be formed or provided through substantially the same process as the via insulating layer VIA and may include substantially the same material as the via insulating layer VIA. In one or more embodiments, the second insulating pattern IP2 may be formed or provided through substantially the same process as the pixel defining layer PDL and may include substantially the same material as the pixel defining layer PDL. In one or more embodiments, the conductive pattern CP may be formed or provided through substantially the same process as the first pixel electrode PE1, the second pixel electrode PE2, and the third pixel electrode PE3 and may include substantially the same material as the first pixel electrode PE1, the second pixel electrode PE2, and the third pixel electrode PE3.

In one or more embodiments, the conductive pattern CP may be electrically connected to the common voltage supply line CVSL of FIG. 1. Accordingly, the common voltage ELVSS of FIG. 3 may be applied to the conductive pattern CP. In one or more embodiments, a DC voltage may be applied to the conductive pattern CP. For example, the DC voltage may include the driving voltage ELVDD or the initialization voltage VINT of FIG. 3. However, embodiments of the present disclosure are not necessarily limited thereto. In one or more embodiments, the conductive pattern CP may be a floating electrode. For example, an electrical signal may not be applied to the conductive pattern CP.

If (e.g., when) the common voltage ELVSS of FIG. 3 is applied to the conductive pattern CP, a DC voltage is applied to the conductive pattern CP, or the conductive pattern CP is a floating electrode, capacitor stabilization may be implemented between the conductive pattern CP and the control signal line CSL (e.g., the control signal line CSL to which a clock signal is applied).

In one or more embodiments, the thickness of the first insulating pattern IP1 in the third direction DR3 may be greater than the thickness of the second insulating pattern IP2 in the third direction DR3.

The first insulating pattern IP1 may include a lower portion IP11 having a first width W1 and an upper portion IP12 arranged or provided on the lower portion IP11 and having a second width W2. In one or more embodiments, the second width W2 may be smaller than the first width W1.

In one or more embodiments, the conductive pattern CP may directly contact an upper surface of the first insulating pattern IP1. For example, the conductive pattern CP may directly contact the upper surface of the lower portion IP11 and the upper surface and the side surface of the upper portion IP12 of the first insulating pattern IP1.

The encapsulation layer ENC may be on the common electrode CE. The encapsulation layer ENC may include a first inorganic encapsulation layer ENC1, an organic encapsulation layer ENC2 on the first inorganic encapsulation layer ENC1, and a second inorganic encapsulation layer ENC3 on the organic encapsulation layer ENC2.

The first inorganic encapsulation layer ENC1 may be arranged or provided entirely (e.g., substantially entirely) in the display area DA and may be arranged provided in a portion of the peripheral area PA. For example, the first inorganic encapsulation layer ENC1 may entirely (e.g., substantially entirely) cover the dam DAM and extend from the display area DA to a portion of the peripheral area PA to cover at least a portion of the support SPM.

The organic encapsulation layer ENC2 may be arranged or provided entirely (e.g., substantially entirely) in the display area DA and may be arranged or provided in a portion of the peripheral area PA. For example, the organic encapsulation layer ENC2 may entirely (e.g., substantially entirely) cover the first dam DAM1 and the second dam DAM2 and may cover a portion of the first dam DAM1. For example, the organic encapsulation layer ENC2 may not be arranged or provided outside the dam DAM due to the dam DAM in the peripheral area PA.

The second inorganic encapsulation layer ENC3 may be arranged or provided entirely (e.g., substantially entirely) in the display area DA and may be arranged or provided in a portion of the peripheral area PA. For example, the second inorganic encapsulation layer ENC3 may entirely (e.g., substantially entirely) cover the dam DAM and extend from the display area DA to a portion of the peripheral area PA to cover at least a portion of the support SPM. Accordingly, an end of the second inorganic encapsulation layer ENC3 may directly contact an end of the first inorganic encapsulation layer ENC1.

Hereinafter, the components of the upper structure 200 will be described in more detail.

The upper structure 200 may include a second substrate SUB2, a color filter layer, a first capping layer CL1, a bank layer BL, a dummy bank layer DBL, a first color conversion layer CCL1, a second color conversion layer CCL2, a light transmission layer LTL, a dummy color conversion layer DCCL, and a second capping layer CL2.

The second substrate SUB2 may be arranged or provided entirely (e.g., substantially entirely) in the display area DA and the peripheral area PA. The second substrate SUB2 may be to transmit light emitted from the first light emitting element LED1, the second light emitting element LED2, and the third light emitting element LED3. For example, the second substrate SUB2 may be made of a transparent (e.g., substantially transparent) resin substrate. The second substrate SUB2 may include an insulating (e.g., electrically insulating) material, such as glass and/or a plastic. In one or more embodiments, the second substrate SUB2 may include an organic polymer material, such as polycarbonate (PC), polyethylene (PE), polypropylene (PP), and/or the like. These materials may be used alone or in combination with each other.

The color filter layer may be under the second substrate SUB2. The color filter layer may be arranged or provided entirely (e.g., substantially entirely) in the display area DA and extend to the peripheral area PA. The color filter layer may be to selectively transmit light having a specific wavelength. The color filter layer may include a first color filter CF1, a second color filter CF2, and a third color filter CF3.

The first color filter CF1 may be to selectively transmit light (e.g., the red light Lr) of the first color. The first color filter CF1 may overlap the first light emitting area EA1, the non-light emitting area NEA, and the peripheral area PA. In one or more embodiments, the first color filter CF1 may not overlap the second light emitting area EA2 and the third light emitting area EA3.

The second color filter CF2 may be to selectively transmit light (e.g., the green light Lg) of the second color. The second color filter CF2 may overlap the second light emitting area EA2, the non-light emitting area NEA, and the peripheral area PA. In one or more embodiments, the second color filter CF2 may not overlap the first light emitting area EA1 and the third light emitting area EA3.

The third color filter CF3 may be to selectively transmit light (e.g., the blue light Lb) of the third color. The third color filter CF3 may overlap the third light emitting area EA3, the non-light emitting area NEA, and the peripheral area PA. In one or more embodiments, the third color filter CF3 may not overlap the first light emitting area EA1 and the second light emitting area EA2.

In the peripheral area PA, the third color filter CF3 may be under the second substrate SUB2, the first color filter CF1 may be under the third color filter CF3, and the second color filter CF2 may be under the first color filter CF1.

A light blocking layer may be under the second substrate SUB2. The light blocking layer may overlap the non-light emitting area NEA. Light emitted from the first light emitting element LED1, the second light emitting element LED2, and the third light emitting element LED3 may transmit only a portion of the upper structure 200. For example, the light emitted from the first light emitting element LED1, the second light emitting element LED2, and the third light emitting element LED3 may transmit only an area of the upper structure 200 that overlaps the first light emitting area EA1, the second light emitting area EA2, and the third light emitting area EA3 and may not transmit through an area of the upper structure 200 that overlaps the non-light emitting area NEA. In one or more embodiments, the light blocking layer may be formed or provided by overlapping and stacking the first color filter CF1, the second color filter CF2, and the third color filter CF3.

In one or more embodiments, the light blocking layer may include a light blocking material. For example, the light blocking material may have a specific color.

The first capping layer CL1 may be under the color filter layer. The first capping layer CL1 may cover the color filter layer. The first capping layer CL1 may be arranged or provided entirely (e.g., substantially entirely) in the display area DA and extend to the peripheral area PA. The first capping layer CL1 may prevent contamination (or reduce a degree or occurrence of contamination) of the color filter layer by blocking external impurities. For example, the first capping layer CL1 may include an inorganic material, such as silicon oxide, silicon nitride, silicon oxynitride, and/or the like. These materials may be used alone or in combination with each other.

The bank layer BL may be under the first capping layer CL1. The bank layer BL may overlap the non-light emitting area NEA. An opening which is to accommodate an ink composition may be defined in the bank layer BL during the process to form or provide the first color conversion layer CCL1, the second color conversion layer CCL2, and the light transmission layer LTL. For example, the bank layer BL may include an organic material, such as polyimide. In one or more embodiments, the bank layer BL may include an organic material containing a light blocking material. In one or more embodiments, the color of the bank layer BL may be black.

The dummy bank layer DBL may be under the first capping layer CL1. The dummy bank layer DBL may be in a portion of the peripheral area PA. An opening which is to accommodate the dummy color conversion layer DCCL may be defined in the dummy bank layer DBL. The dummy bank layer DBL may be formed or provided integrally with the bank layer BL. For example, the dummy bank layer DBL may be formed or provided through substantially the same process as the bank layer BL and may include substantially the same material as the bank layer BL.

An optical filter may be under the first capping layer CL1. For example, the optical filter may include the first color conversion layer CCL1, the second color conversion layer CCL2, and the light transmission layer LTL. The first color conversion layer CCL1 may overlap the first light emitting area EA1, the second color conversion layer CCL2 may overlap the second light emitting area EA2, and the light transmission layer LTL may overlap the third light emitting area EA3. For example, the first color conversion layer CCL1, the second color conversion layer CCL2, and the light transmissive layer LTL may be arranged or provided to fill the opening of the bank layer BL, respectively.

The first color conversion layer CCL1 may include first quantum dots 11c which are excited by light L1 emitted from the first light emitting element LED1 and emit light of the first color (e.g., the red light Lr). In one or more embodiments, the first color conversion layer CCL1 may further include a first polymer material 11b in which first scattering particles 11a are dispersed.

The second color conversion layer CCL2 may include second quantum dots 12c which are excited by light L1 emitted from the second light emitting element LED1 and emit light of the second color (e.g., the green light Lg). In one or more embodiments, the second color conversion layer CCL2 may further include a second polymer material 12b in which second scattering particles 12a are dispersed.

The light transmission layer LTL may be to transmit the light L1 emitted from the third light emitting element LED3 to emit the blue light Lb. In one or more embodiments, the light transmission layer LTL may include a third polymer material 13b in which third scattering particles 13a are dispersed.

For example, each of the first polymer material 11b, the second polymer material 12b, and the third polymer material 13b may include an organic material having light transparency, such as a silicone resin, an epoxy resin, and/or the like. In one or more embodiments, the first polymer material 11b, the second polymer material 12b, and the third polymer material 13b may include substantially the same materials.

For example, the first scattering particles 11a, the second scattering particles 12a, and the third scattering particles 13a may scatter and emit light emitted from the first light emitting element LED1, the second light emitting element LED2, and the third light emitting element LED3. In one or more embodiments, the first scattering particles 11a, the second scattering particles 12a, and the third scattering particles 13a may include substantially the same material.

Accordingly, the first light emitting area EA1 may be to emit the red light Lr, the second light emitting area EA2 may be to emit the green light Lg, and the third light emitting area EA3 may be to emit the blue light Lb.

The dummy color conversion layer DCCL may be under the first capping layer CL1. The dummy color conversion layer DCCL may be in a portion of the peripheral area PA. For example, the dummy color conversion layer DCCL may be arranged or provided to fill the opening of the dummy bank layer DBL. A dummy light transmitting layer may also be arranged or provided in the opening of the dummy bank layer DBL.

The second capping layer CL2 may be on the bank layer BL and the optical filter. The second capping layer CL2 may be arranged or provided entirely (e.g., substantially entirely) in the display area DA and extend to the peripheral area PA. The second capping layer CL2 may be arranged or provided along the profiles of the bank layer BL, the dummy bank layer DBL, the optical filter, and the dummy color conversion layer DCCL. The second capping layer CL2 may act or serve to prevent moisture penetration (or reduce a degree or occurrence of moisture penetration) to prevent deterioration of the optical filter (or to reduce a degree or occurrence of deterioration of the optical filter). For example, the second capping layer CL2 may include an inorganic material, such as silicon oxide, silicon nitride, silicon oxynitride, and/or the like. These materials may be used alone or in combination with each other.

As described in one or more embodiments, the sealing member SM may be between the lower structure 100 and the upper structure 200.

The filling layer 300 may be between the lower structure 100 and the upper structure 200. The filling layer 300 may fill the space between the lower structure 100 and the upper structure 200. The filling layer 300 may be formed or provided by applying or providing (e.g., applying) a filling material on the second capping layer CL2, overlapping the lower structure 100, and then curing the filling material.

The filling layer 300 may include a material which may transmit light. For example, the filling layer 300 may include an organic material. The filling layer 300 may include an organic material, such as a silicone-based resin, an epoxy-based resin, and/or the like. These materials may be used alone or in combination with each other.

Although the display device DD is illustrated in FIGS. 4 and 6 as including two substrates, embodiments of the present disclosure are not necessarily limited thereto. For example, the display device DD may include one substrate, and the optical filter and the color filter layer may be directly on the encapsulation layer ENC. In one or more embodiments, the display device DD may include two substrates, the lower structure 100 may include the optical filter, and the upper structure 200 may include the color filter layer.

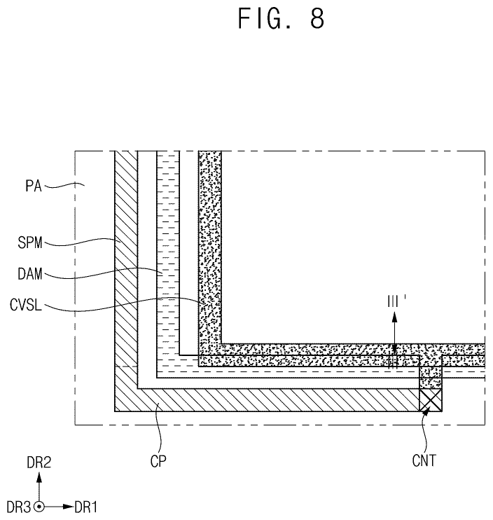

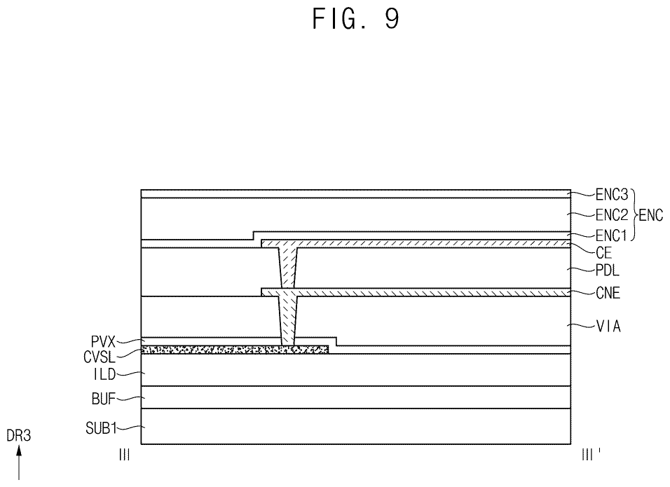

FIG. 8 is an enlarged plan view of a portion of a peripheral area of FIG. 2. FIG. 9 is a cross-sectional view taken along the line III-III′ of FIG. 8. For example, FIG. 8 is an enlarged plan view of a portion of the bottom of the peripheral area PA adjacent to the pad area PDA of FIG. 2.

Referring to FIG. 8, as described in one or more embodiments, the conductive pattern CP of the support SPM may be electrically connected to the common voltage supply line CVSL. In one or more embodiments, at the bottom of the peripheral area PA adjacent to the pad area PDA, a portion of the conductive pattern CP may extend to contact the common voltage supply line CVSL through a contact hole (e.g., via or opening) CNT.

Referring further to FIG. 9, the common voltage supply line CVSL may be arranged or provided in substantially the same layer as the first source electrode SE1, the second source electrode SE2, the third source electrode SE3, the first drain electrode DE1, the second drain electrode DE2, and the third drain electrode DE3. For example, the common voltage supply line CVSL may be formed or provided through substantially the same process as the first source electrode SE1, the second source electrode SE2, the third source electrode SE3, the first drain electrode DE1, the second drain electrode DE2, and the third drain electrode DE3 and may include substantially the same material as the first source electrode SE1, the second source electrode SE2, the third source electrode SE3, the first drain electrode DE1, the second drain electrode DE2, and the third drain electrode DE3.

The connection pattern CNE in the peripheral area PA may be connected to the common voltage connection line CVSL through a contact hole (e.g., via or opening) that penetrates the via insulating layer VIA and the passivation layer PVX. In one or more embodiments, in the peripheral area PA, the common electrode CE may be connected to the connection pattern CNE through a contact hole that penetrates the pixel defining layer PDL. Accordingly, the common voltage supply line CVSL may be electrically connected to the common electrode CE. Through this, the common voltage applied to the common voltage supply line CVSL (e.g., the common voltage ELVSS of FIG. 3) may be transmitted to the common electrode CE through the connection pattern CNE.

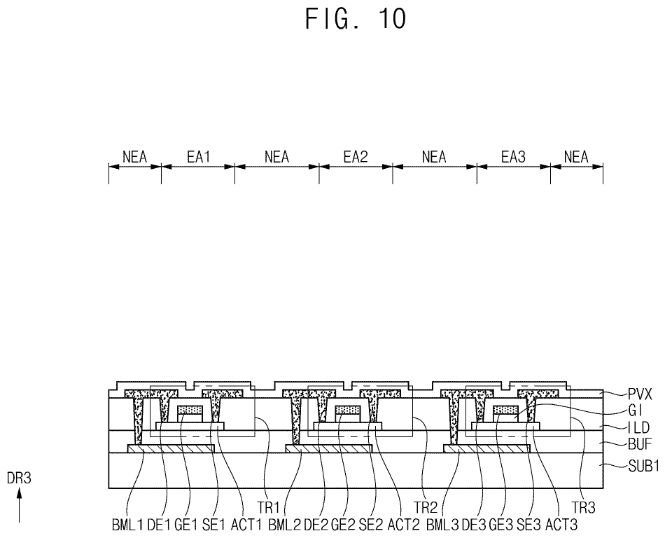

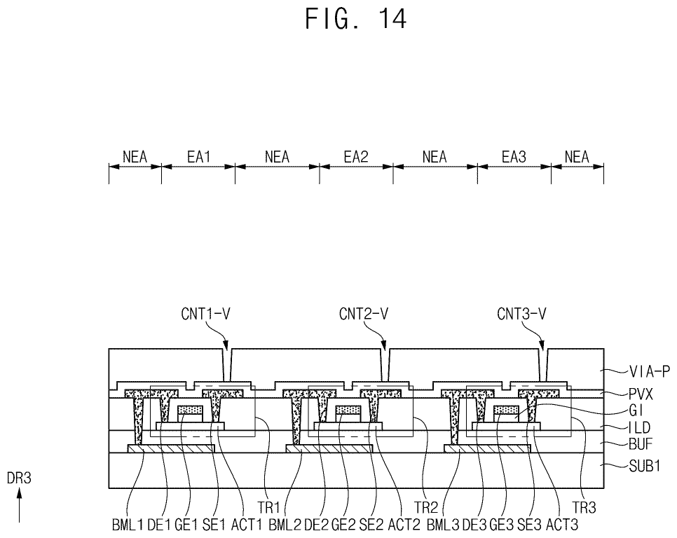

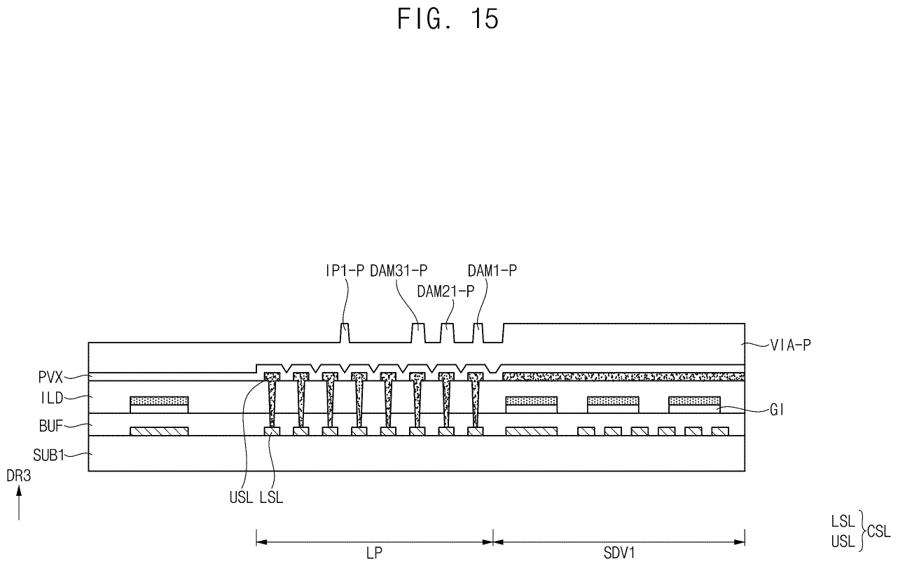

FIGS. 10 to 23 are cross-sectional views illustrating one or more steps (e.g., acts or tasks) of a method for manufacturing the display device of FIGS. 4 and 6. For example, FIGS. 10 to 23 are cross-sectional views illustrating a method of manufacturing the lower structure 100 included in the display device DD of FIGS. 4 and 6. Hereinafter, descriptions that overlap with those of the display device DD described with reference to FIGS. 4 to 7 may not be provided or may be simplified.

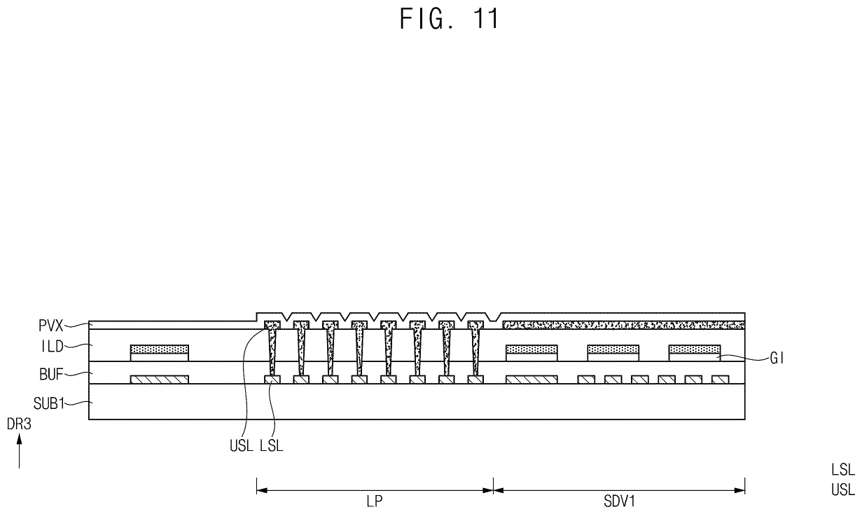

Referring to FIGS. 10 and 11, the first lower conductive layer BML1, the second lower conductive layer BML2, the third lower conductive layer BML3, the buffer layer BUF, the first active pattern ACT1, the second active pattern ACT2, the third active pattern ACT3, the gate insulating layer GI, the first gate electrode GE1, the second gate electrode GE3, the third gate electrode GE3, the interlayer insulating layer ILD, the first source electrode SE1, the second source electrode SE2, the third source electrode SE3, the first drain electrode DE1, the second drain electrode DE2, the third drain electrode DE3, and the passivation layer PVX may be sequentially arranged or provided in the display area DA on the first substrate SUB1.

The buffer layer BUF, the gate insulating layer GI, the interlayer insulating layer ILD, and the passivation layer PVX may also be in the peripheral area PA. In one or more embodiments, the line part LP including the control signal line CSL and the first scan driver SDV1 may be in the peripheral area PA on the first substrate SUB1.

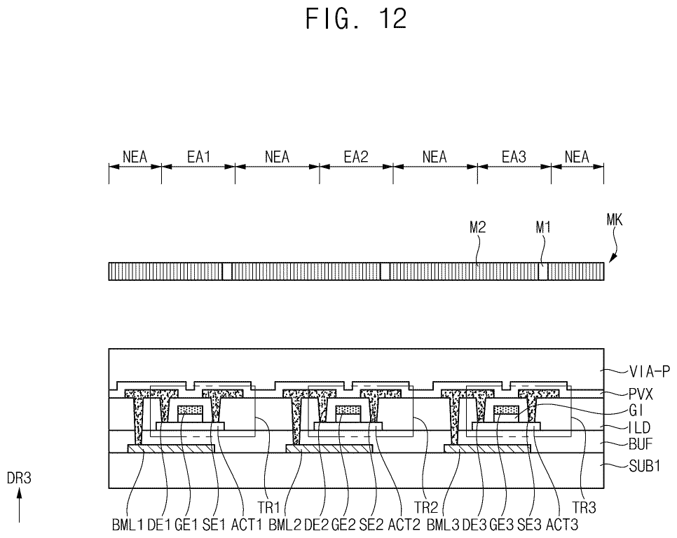

Referring to FIGS. 12, 13, 14, and 15, a preliminary via insulating layer VIA-P may be formed or provided entirely (e.g., substantially entirely) in the display area DA and the peripheral area PA on the passivation layer PVX. The preliminary via insulating layer VIA-P may be formed or provided by using an organic material. For example, the preliminary via insulating layer VIA-P may include a positive photoresist. In one or more embodiments, the preliminary via insulating layer VIA-P may include a negative photoresist.

In one or more embodiments, a halftone mask MK may be on the preliminary via insulating layer VIA-P. The halftone mask MK may include a light transmission portion M1 which is to transmit all of the light, a light blocking portion M2 which is to block all of the light, and a semi-transmission portion M3 which is to transmit a portion of the light.

Through a photo process of exposing and developing the preliminary via insulating layer VIA-P through the halftone mask MK, a portion of the preliminary via insulating layer VIA-P may be removed from the display area DA and the peripheral area PA.

For example, through the photo process, a first via contact hole CNT1-V, a second via contact hole CNT2-V, and a third via contact hole CNT3-V may be formed or provided concurrently (e.g., simultaneously) by removing a portion of the preliminary via insulating layer VIA-P that corresponds to the light transmission portion M1 in the display area DA. The first via contact hole CNT1-V, the second via contact hole CNT2-V, and the third via contact hole CNT3-V may be formed or provided to correspond to the first source electrode SE1, the second source electrode SE2, and the third source electrode SE3, respectively. In one or more embodiments, through the photo process, a first portion of the preliminary via insulating layer VIA-P that corresponds to the semi-transmission portion M3 may be removed in the peripheral area PA. In one or more embodiments, through the photo process, a preliminary first dam DAM1-P, a preliminary first lower dam DAM21-P, a preliminary second lower dam DAM31-P, and a preliminary first insulating pattern IP1-P may be formed or provided by remaining a second portion of the preliminary via insulating layer VIA-P that corresponds to the light blocking portion M2 in the peripheral area PA.

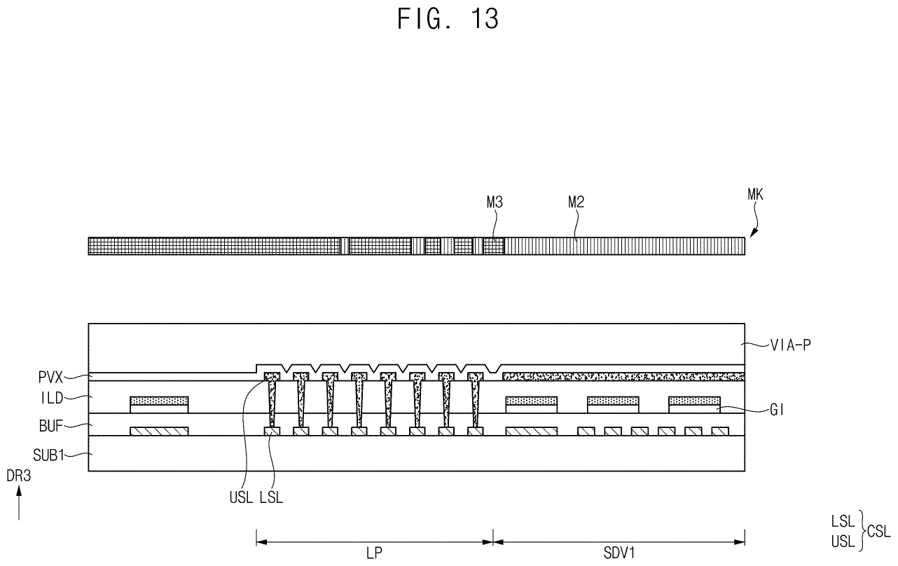

In one or more embodiments, the photo process has been described by using the example where the preliminary via insulating layer VIA-P includes a positive photoresist. In one or more embodiments, if (e.g., when) the preliminary via insulating layer VIA-P includes a negative photoresist, the positions of the light transmission portion M1 and the light blocking portion M2 of the halftone mask MK of FIGS. 12 and 13 may be changed. In one or more embodiments, the first via contact hole CNT1-V, the second via contact hole CNT2-V, and the third via contact hole CNT3-V may formed or provided by removing a portion of the preliminary via insulating layer VIA-P that corresponds to the light blocking portion M2 of the halftone mask MK, and the preliminary first dam DAM1-P, the preliminary first lower dam DAM21-P, the preliminary second lower dam DAM31-P, and the preliminary first insulating pattern IP1-P may be formed or provided by remaining a portion of the preliminary via insulating layer VIA-P that corresponds to the light transmission portion M1 in the peripheral area PA.

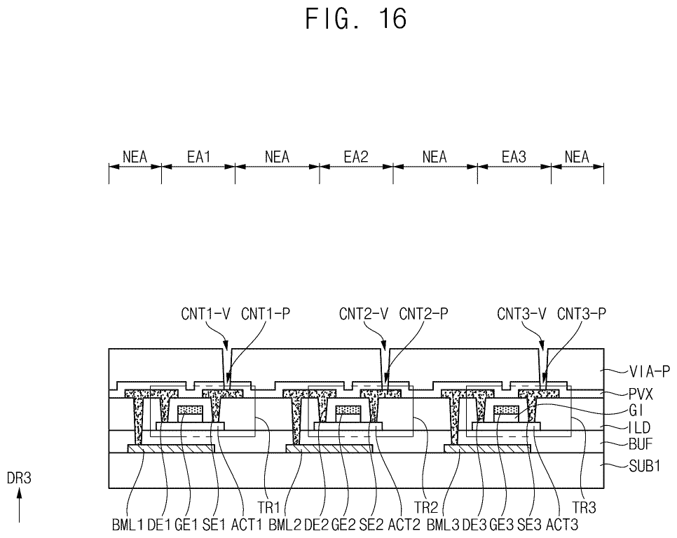

Referring to FIG. 16, a portion of the passivation layer PVX exposed by the first via contact hole CNT1-V, the second via contact hole CNT2-V, and the third via contact hole CNT3-V may be removed through an etching process by using the preliminary via insulating layer VIA-P as a mask. Accordingly, a first contact hole CNT1-P that exposes the first source electrode SE1, a second contact hole CNT2-P that exposes the second source electrode SE2, and a third contact hole CNT3-P that exposes the third source electrode SE3 may be formed or provided to the passivation layer PVX. The first via contact hole CNT1-V, the second via contact hole CNT2-V, and the third via contact hole CNT3-V may expose the first contact hole CNT1-P, the second contact hole CNT2-P, and the third contact hole CNT3-P, respectively.

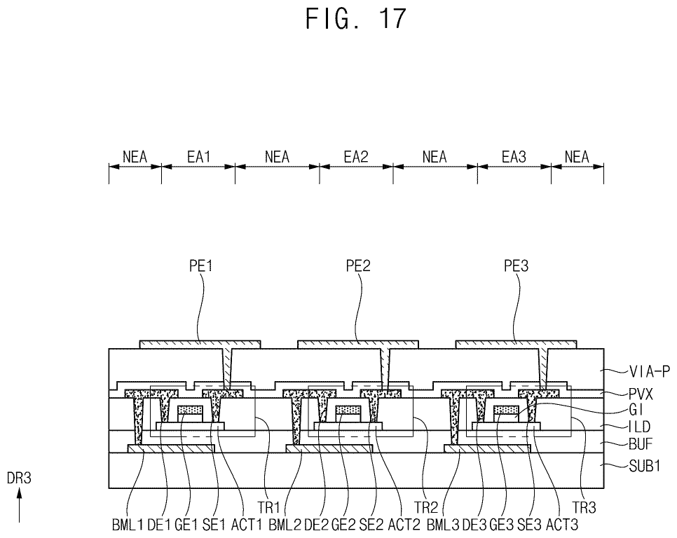

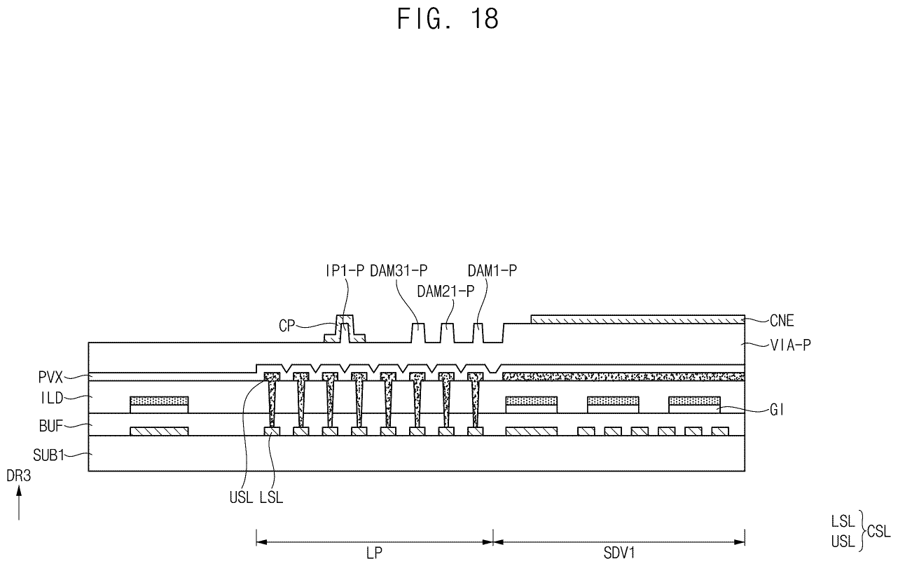

Referring to FIGS. 17 and 18, the first pixel electrode PE1, the second pixel electrode PE2, and the third pixel electrode PE3 may be in the display area DA on the preliminary via insulating layer VIA-P. The first pixel electrode PE1 may fill the first via contact hole CNT1-V and the first contact hole CNT1-P, the second pixel electrode PE2 may fill the second via contact hole CNT2-V and the second contact hole CNT2-P, and the third pixel electrode PE3 may fill the third via contact hole CNT3-V and the third contact hole CNT3-P.

The connection pattern CNE and the conductive pattern CP may be in the peripheral area PA on the preliminary via insulating layer VIA-P. The conductive pattern CP may be on the preliminary first insulating pattern IP1-P. For example, the conductive pattern CP may be formed or provided to cover the preliminary first insulating pattern IP1-P.

The connection pattern CNE and the conductive pattern CP may be formed or provided concurrently (e.g., simultaneously) through substantially the same process (e.g., etching process) as the first pixel electrode PE1, the second pixel electrode PE2, and the third pixel electrode PE3.

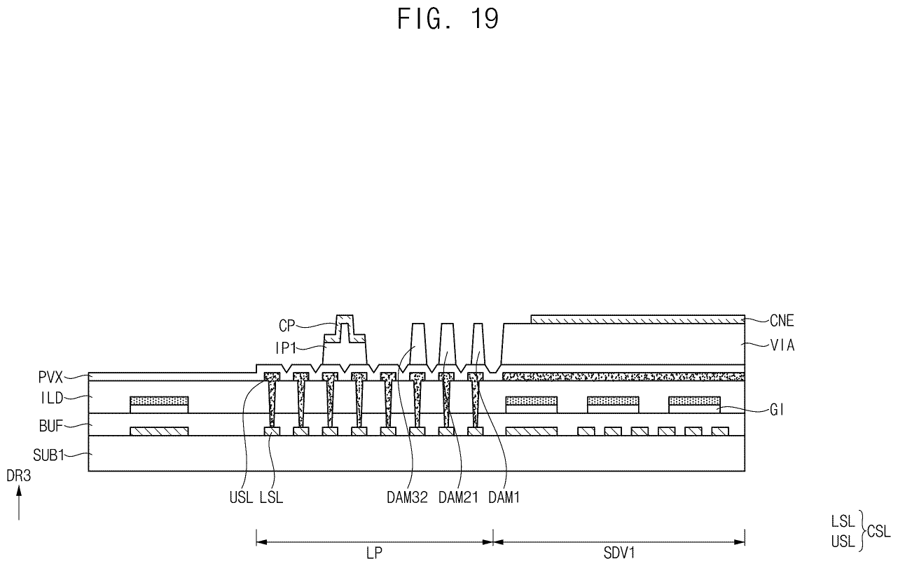

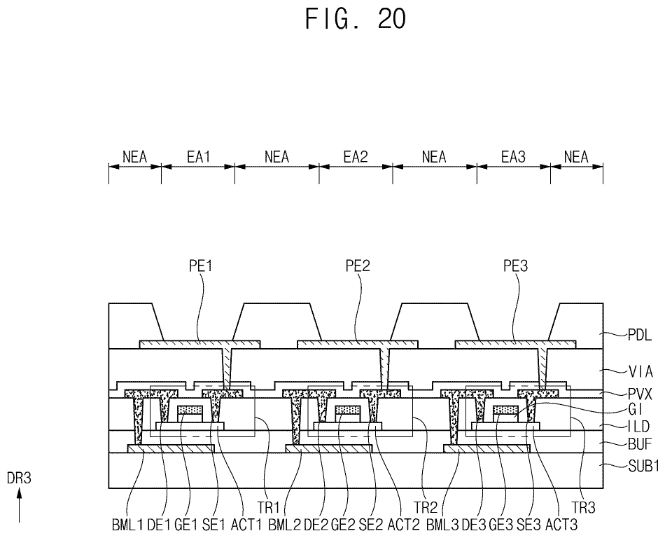

Referring to FIG. 19, in one or more embodiments, through an ashing process, a first portion of the preliminary via insulating layer VIA-P, a portion of which is removed that corresponds to the semi-transmission portion M3 through the photo process, may be completely (e.g., substantially completely) removed from the peripheral area PA. In one or more embodiments, the passivation layer PVX may be exposed in an area where the first portion of the preliminary via insulating layer VIA-P is removed. Accordingly, as illustrated in FIG. 20, the via insulating layer VIA may be arranged or provided entirely (e.g., substantially entirely) in the display area DA and may be formed or provided in a portion of the peripheral area PA. In one or more embodiments, the first dam DAM1, the first lower dam DAM21, the second lower dam DAM31, and the first insulating pattern IP1 may be formed or provided at positions that correspond to the preliminary first dam DAM1-P, the preliminary first lower dam DAM21-P, the preliminary second lower dam DAM31-P, and the preliminary first insulating pattern IP1-P, respectively.

In one or more embodiments, the conductive pattern CP may act or serve to protect the preliminary first insulating pattern IP1-P so that the preliminary first insulating pattern IP1-P remains undamaged (e.g., without being removed) by the ashing process and the first insulating pattern IP1 is formed or provided.

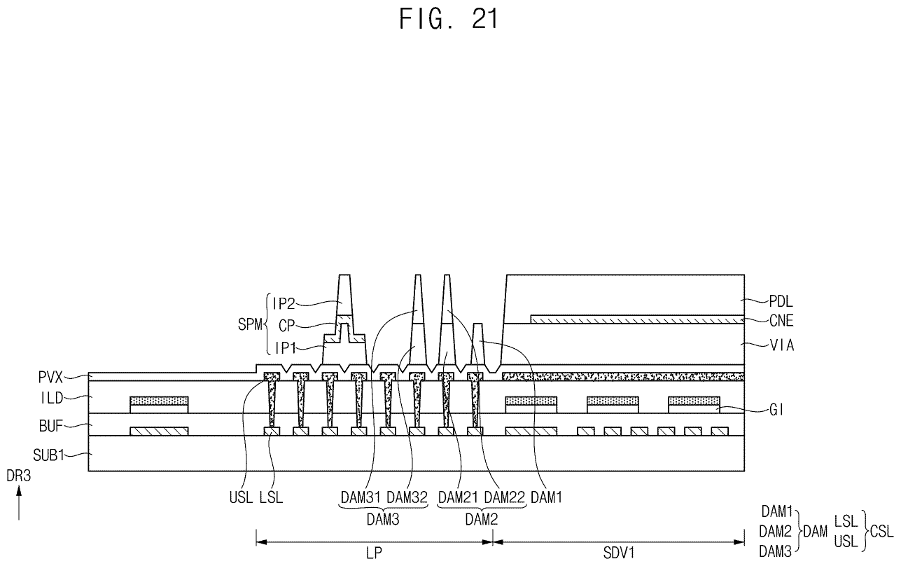

Referring to FIGS. 20 and 21, the pixel defining layer PDL may be formed or provided on the via insulating layer VIA. The pixel defining layer PDL may be arranged or provided entirely (e.g., substantially entirely) in the display area DA and may be formed or provided in a portion of the peripheral area PA. The pixel openings that expose the first pixel electrode PE1, the second pixel electrode PE2, and the third pixel electrode PE3, respectively, may be formed or provided (or defined) in the pixel defining layer PDL.

The first upper dam DAM22 may be formed or provided on the first lower dam DAM21, the second upper dam DAM32 may be formed or provided on the second lower dam DAM31, and the second insulating pattern IP2 may be formed or provided on the conductive pattern CP. The first upper dam DAM22, the second upper dam DAM32, and the second insulating pattern IP2 may be formed or provided concurrently (e.g., simultaneously) through substantially the same process as the pixel defining layer PDL.

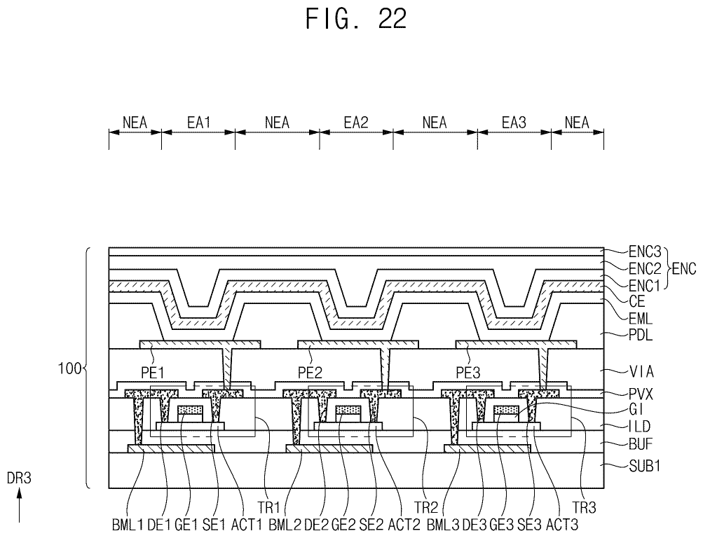

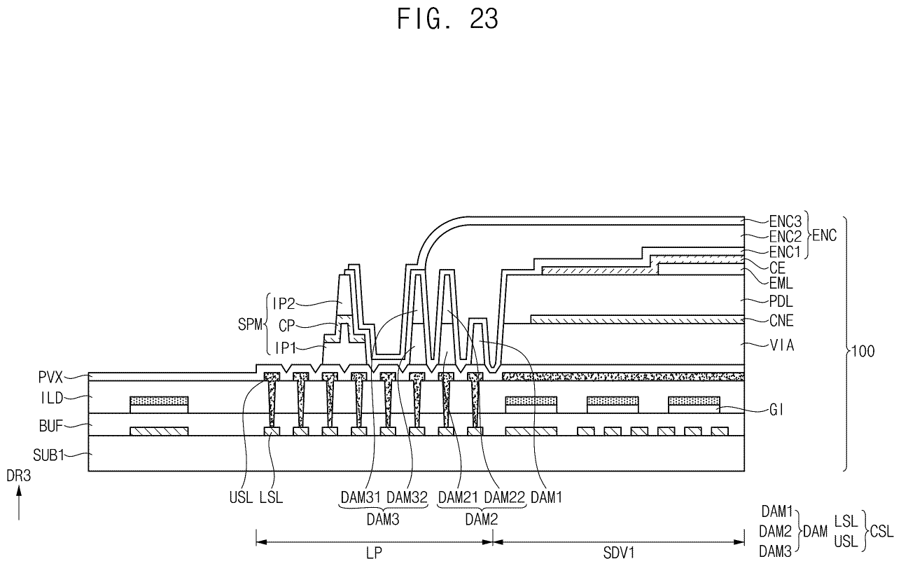

Referring to FIGS. 22 and 23, the light emitting layer EML, the common electrode CE, the first inorganic encapsulation layer ENC1, the organic encapsulation layer ENC2, and the second inorganic encapsulation layer ENC3 may be formed or provided sequentially on the pixel defining layer PDL. The light emitting layer EML, the common electrode CE, the first inorganic encapsulation layer ENC1, the organic encapsulation layer ENC2, and the second inorganic encapsulation layer ENC3 may be arranged or provided entirely (e.g., substantially entirely) in the display area DA, and may be formed or provided in a portion of the peripheral area PA.

Accordingly, the lower structure 100 included in the display device DD of FIGS. 4 and 6 may be manufactured.

In a comparative example, a support arranged or provided in the peripheral area PA and supporting the mask used during the mask process may include the first insulating pattern IP1 and the second insulating pattern IP2 that is directly arranged or provided on the first insulating pattern IP1. In one or more embodiments, the first insulating pattern IP1 of the support may be damaged due to the ashing process for the via insulating layer VIA.

Referring again to FIGS. 1 to 23, in the display device DD according to one or more embodiments of the present disclosure, the support SPM arranged or provided in the peripheral area PA and supporting the mask used during the mask process may include the first insulating pattern IP1, the second insulating pattern IP2 on the first insulating pattern IP1, and the conductive pattern CP between the first insulating pattern IP1 and the second insulating pattern IP2. Accordingly, the conductive pattern CP may prevent the first insulating pattern IP1 of the support SPM from being damaged (or reduce a degree to or occurrence of which the first insulating pattern IP1 of the support SPM is damaged) due to an ashing process for the via insulating layer VIA. Accordingly, a degree or occurrence of damages to the scan driver (e.g., the first scan driver SDV1 and the second scan driver SDV2 of FIG. 2) due to moisture penetration may be minimized or reduced. For example, the conductive pattern CP may act or serve to prevent the first insulating pattern IP1 of the support SPM from being damaged, or reduce the degree or occurrence of damage, due to an ashing process for the via insulating layer VIA. This protective function of the conductive pattern CP ensures the integrity of the first insulating pattern IP1 during the manufacturing process, thereby enhancing the overall reliability of the display device DD. Consequently, the likelihood of damages to the scan driver (e.g., the first scan driver SDV1 and the second scan driver SDV2 of FIG. 2) due to moisture penetration may be minimized or reduced. This configuration or arrangement not only improves or enhances the durability of the display device but also ensures stable operation under one or more environmental conditions, thereby extending the lifespan of the device.

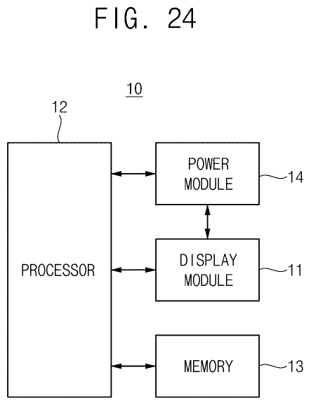

FIG. 24 is a block diagram illustrating an electronic device according to one or more embodiments of the present disclosure.

Referring to FIG. 24, an electronic device 10 may include a display module 11, a processor 12, a memory 13, and a power module 14.

A display device according to one or more embodiments (e.g., the display device DD of FIGS. 1 and 2) may be applied to one or more suitable electronic devices 10. The electronic device 10 may include the display device as described in one or more embodiments and may further include modules and/or devices with additional functions other than the display device.

The processor 12 may include at least one selected from among a central processing unit (CPU), an application processor (AP), a graphic processing unit (GPU), a communication processor (CP), an image signal processor (ISP), and a controller. The processor 12 may be to control the display device.

The memory 15 may be to store data information desired or necessary for the operation of the processor 12 or the display module 11. If (e.g., when) the processor 12 executes the application stored in the memory 15, an image data signal and/or an input control signal may be transmitted to the display module 11, and the display module 11 may process the received signal and output image information through a display screen.

The power module 14 may include a power supply module, such as a power adapter or a battery device, and a power conversion module which is to convert the power supplied by the power supply module to generate power desired or required for the operation of the electronic device 10.

At least one of each component of the electronic device 10 as described in one or more embodiments may be included in the display device according to one or more embodiments. In one or more embodiments, one or more of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

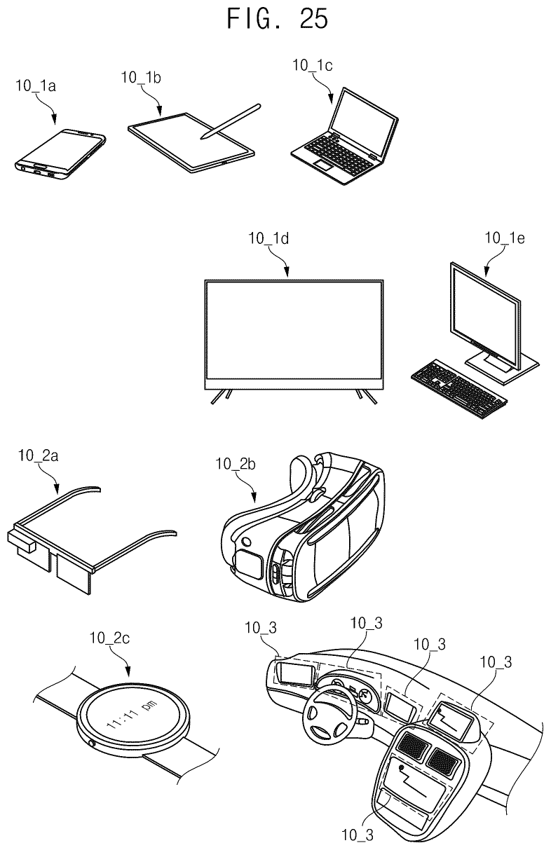

FIG. 25 are schematic diagrams illustrating an electronic device according to one or more suitable embodiments.

Referring to FIG. 25, one or more suitable electronic devices 10 to which display devices according to one or more embodiments (e.g., the display device DD of FIGS. 1 and 2) are applied may include not only image display electronic devices, such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) on a dashboard, and a room mirror display, and/or the like.

One or more embodiments of the present disclosure may be applied to one or more suitable display devices. For example, the present disclosure is applicable to one or more suitable display devices, such as display devices for vehicles, ships and/or aircraft, portable communication devices, display devices for exhibition or information transmission, medical display devices, and/or the like.

A display device/apparatus, an electronic device/apparatus, a vehicle, a device/apparatus for manufacturing substantially the same and/or any other relevant devices, apparatus, or components according to embodiments of the present disclosure described herein may be implemented by utilizing any suitable hardware, firmware (e.g., an application-specific integrated circuit), software, or a combination of software, firmware, and hardware. For example, the one or more suitable components of the device may be formed or provided on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components to perform the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

It will be understood by one of ordinary skill in the art to which the present disclosure belongs that the present disclosure may be implemented in one or more suitable forms without changing the spirit and scope of the present disclosure. Therefore, it will be understood that the one or more embodiments as described in the present disclosure are illustrative rather than being restrictive in all aspects. It will be understood that the scope of the present disclosure are defined by the scope of the appended claims and equivalents thereof rather than the detailed description as described above and all modifications and alterations derived from the appended claims and their equivalents fall within the scope of the present disclosure.

What is claimed is:

1. A display device comprising:
a substrate comprising a display area and a peripheral area around at least a portion of the display area;
a common voltage supply line provided in the peripheral area and configured to have a common voltage applied to it;
a support provided in the peripheral area and comprising a first insulating pattern, a second insulating pattern on the first insulating pattern, and a conductive pattern between the first insulating pattern and the second insulating pattern;
at least one dam provided between the support and the display area in a plan view and around the display area; and
a light emitting element comprising a pixel electrode, a light emitting layer, and a common electrode that are sequentially provided in the display area on the substrate.

2. The display device as claimed in claim 1, wherein the conductive pattern comprises substantially the same material as the pixel electrode.

3. The display device as claimed in claim 1, wherein the conductive pattern is electrically connected to the common voltage supply line.

4. The display device as claimed in claim 3, wherein the peripheral area comprises a pad area where a pad electrode is provided, and
at a bottom of the peripheral area adjacent to the pad area, the conductive pattern contacts the common voltage supply line through a contact hole.

5. The display device as claimed in claim 1, wherein the conductive pattern is a floating electrode.

6. The display device as claimed in claim 1, wherein the conductive pattern is configured to have a direct current (DC) voltage applied to it.

7. The display device as claimed in claim 1, wherein a thickness of the first insulating pattern is greater than a thickness of the second insulating pattern.

8. The display device as claimed in claim 1, wherein the first insulating pattern comprises a lower portion having a first width and an upper portion having a second width that is smaller than the first width.

9. The display device as claimed in claim 8, wherein the conducive pattern contacts an upper surface and a side surface of the upper portion of the first insulating pattern.

10. The display device as claimed in claim 1, further comprising:
an inorganic insulating layer on the substrate;
an organic insulating layer on the inorganic insulating layer; and
a pixel defining layer provided on the organic insulating layer and defining a pixel opening that exposes at least a portion of the pixel electrode,
wherein the first insulating pattern comprises substantially the same material as the organic insulating layer, and
wherein the second insulating pattern comprises substantially the same material as the pixel defining layer.

11. The display device as claimed in claim 10, wherein the at least one dam comprises:
a first dam comprising substantially the same material as the organic insulating layer;
a second dam provided outside of the first dam and comprising: a first lower dam comprising substantially the same material as the organic insulating layer and a first upper dam provided on the first lower dam and comprising substantially the same material as the pixel defining layer; and
a third dam provided outside of the second dam and comprising: a second lower dam comprising substantially the same material as the organic insulating layer and a second upper dam provided on the second lower dam and comprising substantially the same material as the pixel defining layer.

12. The display device as claimed in claim 1, further comprising:
a scan driver provided in the peripheral area and configured to provide a scan signal to a plurality of pixels in the display area; and
a line part provided outside the scan driver in the peripheral area and configured to provide a control signal to the scan driver,
wherein the support at least partially overlaps the line part in the plan view.

13. The display device as claimed in claim 1, further comprising:
a color conversion layer provided on the light emitting element and configured to convert a wavelength of light emitted from the light emitting layer; and
a color filter layer on the color conversion layer.

14. The display device as claimed in claim 13, further comprising:
a sealing member outside the support in the peripheral area.

15. A method comprising:
providing a support comprising a first insulating pattern, a second insulating pattern on the first insulating pattern, and a conductive pattern between the first insulating pattern and the second insulating pattern in a peripheral area on a substrate, wherein the substrate comprises a display area and the peripheral area around at least a portion of the display area;
providing at least one dam between the support and the display area in a plan view and around the display area;
providing a common voltage supply line which is to receive a common voltage in the peripheral area; and
providing a light emitting element comprising a pixel electrode, a light emitting layer, and a common electrode that are sequentially provided in the display area on the substrate,
wherein the method is a method for manufacturing a display device.

16. The method as claimed in claim 15, wherein the providing of the support comprises:
providing a preliminary organic insulating layer in the display area and the peripheral area on the substrate;
exposing and developing the preliminary organic insulating layer through a halftone mask, wherein the halftone mask comprises a light transmission portion, a light blocking portion, and a semi-transmission portion, to remove a first portion of the preliminary organic insulating layer that corresponds to the semi-transmission portion in the peripheral area and leaving a second portion of the preliminary organic insulating layer that corresponds to the light transmission portion or the light blocking portion to provide a preliminary first insulating pattern; and
providing the conductive pattern that covers the preliminary first insulating pattern.

17. The method as claimed in claim 16, after the providing of the conductive pattern that covers the preliminary first insulating pattern, the providing of the support further comprises:
removing the first portion of the preliminary organic insulating layer in the peripheral area through an ashing process to provide an organic insulating layer and the first insulating pattern, with the organic insulating layer entirely in the display area and in a portion of the peripheral area.

18. The method as claimed in claim 17, after the providing of the first insulating pattern, further comprising:
providing a pixel defining layer that defines a pixel opening that exposes at least a portion of the pixel electrode on the organic insulating layer,
wherein the second insulating pattern is provided through substantially the same process as the pixel defining layer.

19. The method as claimed in claim 15, wherein the conductive pattern is provided through substantially the same process as the pixel electrode, and
the conductive pattern is electrically connected to the common voltage supply line.

20. An electronic device comprising:
a display device comprising:
a substrate comprising a display area and a peripheral area around at least a portion of the display area;
a common voltage supply line provided in the peripheral area and configured to have a common voltage applied to it;
a support provided in the peripheral area and comprising a first insulating pattern, a second insulating pattern on the first insulating pattern, and a conductive pattern between the first insulating pattern and the second insulating pattern;
at least one dam provided between the support and the display area in a plan view and around the display area; and
a light emitting element comprising a pixel electrode, a light emitting layer, and a common electrode that are sequentially provided in the display area on the substrate; and
a processor to control the display device by providing an image data signal and an input control signal to the display device.
